(19) United States
(12) Patent Application Publication
(10) Pub. No.: US 2006/0005876 A1
(43) Pub. Date: Jan. 12, 2006

(54) Mobile photovoltaic communication facilities

(76) Inventors: Russell Gaudiana, Merrimack, NH (US); Daniel Patrick McGahn, Boston, MA (US)

Correspondence Address: Konarka Technologies, Inc., Suite 12, 116 John Street, Lowell, MA, 01852, US

(21) Appl. No.: 11/221,439

(22) Filed: Sep. 8, 2005

Related U.S. Application Data
(63) Continuation-in-part of application No. 10/258,708, filed on May 22, 2003, now Pat. No. 6,933,436.
(63) Continuation-in-part of application No. 10/258,709, filed on Feb. 27, 2003, now Pat. No. 6,812,399.
(63) Continuation-in-part of application No. 10/258,713, filed on May 16, 2005.
(63) Continuation-in-part of application No. 10/351,607, filed on Jan. 24, 2003, now Pat. No. 6,913,713.
Application No. 10/351,607 is a continuation-in-part of application No. 10/057,394, filed on Jan. 25, 2002, now Pat. No. 6,706,963.
(63) Continuation-in-part of application No. 10/350,913, filed on Jan. 24, 2003, now Pat. No. 6,858,158.
Application No. 10/350,913 is a continuation-in-part of application No. 10/057,394, filed on Jan. 25, 2002, now Pat. No. 6,706,963.
(63) Continuation-in-part of application No. 10/350,912, filed on Jan. 24, 2003, now Pat. No. 6,900,382.
Application No. 10/350,912 is a continuation-in-part of application No. 10/057,394, filed on Jan. 25, 2002, now Pat. No. 6,706,963.
(63) Continuation-in-part of application No. 10/350,812, filed on Jan. 24, 2003.
Application No. 10/350,812 is a continuation-in-part of application No. 10/057,394, filed on Jan. 25, 2002, now Pat. No. 6,706,963.
(63) Continuation-in-part of application No. 10/350,800, filed on Jan. 24, 2003.
Application No. 10/350,800 is a continuation-in-part of application No. 10/057,394, filed on Jan. 25, 2002, now Pat. No. 6,706,963.
(63) Continuation-in-part of application No. 10/351,298, filed on Jan. 24, 2003, now Pat. No. 6,924,427.
Application No. 10/351,298 is a continuation-in-part of application No. 10/057,394, filed on Jan. 25, 2002, now Pat. No. 6,706,963.
(63) Continuation-in-part of application No. 10/351,260, filed on Jan. 24, 2003.
Application No. 10/351,260 is a continuation-in-part of application No. 10/057,394, filed on Jan. 25, 2002, now Pat. No. 6,706,963.
(63) Continuation-in-part of application No. 10/351,249, filed on Jan. 24, 2003.
(63) Continuation-in-part of application No. 10/350,919, filed on Jan. 24, 2003.
Application No. 10/350,919 is a continuation-in-part of application No. 10/057,394, filed on Jan. 25, 2002, now Pat. No. 6,706,963.
(63) Continuation-in-part of application No. 10/351,264, filed on Jan. 24, 2003.
(63) Continuation-in-part of application No. 10/351,265, filed on Jan. 24, 2003.
Application No. 10/351,265 is a continuation-in-part of application No. 10/057,394, filed on Jan. 25, 2002, now Pat. No. 6,706,963.
(63) Continuation-in-part of application No. 10/351,251, filed on Jan. 24, 2003.
Application No. 10/351,251 is a continuation-in-part of application No. 10/057,394, filed on Jan. 25, 2002, now Pat. No. 6,706,963.
(63) Continuation-in-part of application No. 10/351,250, filed on Jan. 24, 2003, now Pat. No. 6,949,400.
Application No. 10/351,250 is a continuation-in-part of application No. 10/057,394, filed on Jan. 25, 2002, now Pat. No. 6,706,963.
(63) Continuation-in-part of application No. 10/486,116, filed on Jul. 13, 2004.
(63) Continuation-in-part of application No. 10/494,560, filed on Nov. 17, 2004.
(63) Continuation-in-part of application No. 10/498,484, filed on Jun. 14, 2004.
(63) Continuation-in-part of application No. 10/504,091, filed on Aug. 11, 2004.
(63) Continuation-in-part of application No. 10/509,935, filed on Aug. 19, 2005.
(63) Continuation-in-part of application No. 10/515,159, filed on Jun. 21, 2005.
(63) Continuation-in-part of application No. 10/723,554, filed on Nov. 26, 2003.
Application No. 10/723,554 is a continuation-in-part of application No. 10/395,823, filed on Mar. 24, 2003.
(63) Continuation-in-part of application No. 10/897,268, filed on Jul. 22, 2004.
(63) Continuation-in-part of application No. 11/000,276, filed on Nov. 30, 2004.
(63) Continuation-in-part of application No. 11/033,217, filed on Jan. 10, 2005.
(63) Continuation-in-part of application No. 10/522,862, filed on Sep. 6, 2005.
(60) Provisional application No. 60/351,691, filed on Jan. 25, 2002.
(60) Provisional application No. 60/353,138, filed on Feb. 1, 2002.
(60) Provisional application No. 60/368,832, filed on Mar. 29, 2002.
(60) Provisional application No. 60/400,289, filed on Jul. 31, 2002.
(60) Provisional application No. 60/351,691, filed on Jan. 25, 2002.
(60) Provisional application No. 60/368,832, filed on Mar. 29, 2002.
(60) Provisional application No. 60/400,289, filed on Jul. 31, 2002.
(60) Provisional application No. 60/351,691, filed on Jan. 25, 2002.
(60) Provisional application No. 60/368,832, filed on Mar. 29, 2002.
(60) Provisional application No. 60/400,289, filed on Jul. 31, 2002.
(60) Provisional application No. 60/351,691, filed on Jan. 25, 2002.
(60) Provisional application No. 60/368,832, filed on Mar. 29, 2002.
(60) Provisional application No. 60/390,071, filed on Jun. 20, 2002.
(60) Provisional application No. 60/396,173, filed on Jul. 16, 2002.
(60) Provisional application No. 60/400,289, filed on Jul. 31, 2002.
(60) Provisional application No. 60/390,071, filed on Jun. 20, 2002.
(60) Provisional application No. 60/400,289, filed on Jul. 31, 2002.
(60) Provisional application No. 60/351,691, filed on Jan. 25, 2002.
(60) Provisional application No. 60/368,832, filed on Mar. 29, 2002.
(60) Provisional application No. 60/400,289, filed on Jul. 31, 2002.
(60) Provisional application No. 60/427,642, filed on Nov. 19, 2002.
(60) Provisional application No. 60/351,691, filed on Jan. 25, 2002.
(60) Provisional application No. 60/368,832, filed on Mar. 29, 2002.
(60) Provisional application No. 60/400,289, filed on Jul. 31, 2002.
(60) Provisional application No. 60/400,289, filed on Jul. 31, 2002.
(60) Provisional application No. 60/351,691, filed on Jan. 25, 2002.
(60) Provisional application No. 60/368,832, filed on Mar. 29, 2002.
(60) Provisional application No. 60/400,289, filed on Jul. 31, 2002.
(60) Provisional application No. 60/400,289, filed on Jul. 31, 2002.
(60) Provisional application No. 60/427,642, filed on Nov. 19, 2002.
(60) Provisional application No. 60/351,691, filed on Jan. 25, 2002.
(60) Provisional application No. 60/368,832, filed on Mar. 29, 2002.
(60) Provisional application No. 60/427,642, filed on Nov. 19, 2002.
(60) Provisional application No. 60/400,289, filed on Jul. 31, 2002.
(60) Provisional application No. 60/351,691, filed on Jan. 25, 2002.
(60) Provisional application No. 60/368,832, filed on Mar. 29, 2002.
(60) Provisional application No. 60/427,642, filed on Nov. 19, 2002.
(60) Provisional application No. 60/400,289, filed on Jul. 31, 2002.
(60) Provisional application No. 60/351,691, filed on Jan. 25, 2002.
(60) Provisional application No. 60/368,832, filed on Mar. 29, 2002.
(60) Provisional application No. 60/427,642, filed on Nov. 19, 2002.
(60) Provisional application No. 60/400,289, filed on Jul. 31, 2002.
(60) Provisional application No. 60/368,832, filed on Mar. 29, 2002.
(60) Provisional application No. 60/400,289, filed on Jul. 31, 2002.
(60) Provisional application No. 60/495,302, filed on Aug. 15, 2003.
(60) Provisional application No. 60/526,373, filed on Dec. 1, 2003.
(60) Provisional application No. 60/546,818, filed on Feb. 19, 2004.
(60) Provisional application No. 60/637,844, filed on Dec. 20, 2004.
(60) Provisional application No. 60/638,070, filed on Dec. 21, 2004.
(60) Provisional application No. 60/664,298, filed on Mar. 22, 2005.
(60) Provisional application No. 60/663,985, filed on Mar. 21, 2005.
(60) Provisional application No. 60/664,114, filed on Mar. 21, 2005.
(60) Provisional application No. 60/664,336, filed on Mar. 23, 2005.

(30) Foreign Application Priority Data
Apr. 27, 2000 (AT) 734/2000
Apr. 27, 2000 (AT) 735/2000
Apr. 27, 2000 (AT) 733/2000
Aug. 7, 2001 (AT) 1231/2001
Nov. 8, 2001 (SE) 0103740-7
Dec. 13, 2001 (DE) 101 61 303.2
Feb. 12, 2002 (DE) 102 05 579.3
May 22, 2002 (AT) 775/2002
Jun. 14, 2002 (DE) 102 26 669.7
Aug. 8, 2002 (DE) 102 36 464.8

(51) Int. Cl. H01L 31/00

(52) U.S. Cl. 136/251; 136/244; 136/293; 136/291

(57) ABSTRACT

Photovoltaic cells, facilities, systems and methods, as well as related compositions, are disclosed. Embodiments involve associating various photovoltaic cells and facilities with various mobile communication facilities.

### CROSS-REFERENCE TO RELATED APPLICATIONS

[The present application is a continuation-in-part of, and claims priority under U.S.C. §120 to, U.S. Ser. No. 10/258,708, filed Oct. 25, 2002 [Q-04], which, in turn, claims priority under 35 U.S.C. §371 to international patent application serial number PCT/AT01/00129, filed Apr. 27, 2001, which, in turn, claims priority to Austrian patent application serial number 734/2000, filed Apr. 27, 2000. The present application is a continuation-in-part of, and claims priority under U.S.C. §120 to, U.S. Ser. No. 10/258,709, filed Oct. 25, 2002 [Q-05], which, in turn, claims priority under 35 U.S.C. §371 to international patent application serial number PCT/AT01/00128, filed Apr. 27, 2001, which, in turn, claims priority to Austrian patent application serial number 735/2000, filed Apr. 27, 2000. The present application is a continuation-in-part of, and claims priority under U.S.C. §120 to, U.S. Ser. No. 10/258,713, filed Oct. 25, 2002 [Q-03], which, in turn, claims priority under 35 U.S.C. §371 to international patent application serial number PCT/AT01/00130, filed Apr. 27, 2001, which, in turn, claims priority to Austrian patent application serial number 733/2000, filed Apr. 27, 2000. The present application is a continuation-in-part of, and claims priority under 35 U.S.C. § 120 to, U.S. Ser. No. 10/351,607, filed Jan. 24, 2003 [KON-002], which, in turn, is a continuation-in-part of U.S. Ser. No. 10/057,394, filed Jan. 25, 2002, now U.S. Pat. No. 6,706,963 [KON-001], and also claims the benefit under 35 U.S.C. §1119 of U.S. Ser. Nos. 60/351,691, filed Jan. 25, 2002 [KON-003PR], 60/353,138, filed Feb. 1, 2002 [KON-002PR], 60/368,832 filed Mar. 29, 2002 [KON-004PR], and 60/400,289, filed Jul. 31, 2002 [KON-011PR]. The present application is a continuation-in-part of, and claims priority under 35 U.S.C. §120 to, U.S. Ser. No. 10/350,913, filed Jan. 24, 2003 [KON-003], which, in turn, is a continuation-in-part of U.S. Ser. No. 10/057,394, filed Jan. 25, 2002, now U.S. Pat. No. 6,706,963 [KON-001], and also claims the benefit under 35 U.S.C. §119 of U.S. Ser. Nos. 60/351,691, filed Jan. 25, 2002 [KON-003PR], 60/368,832 filed Mar. 29, 2002 [KON-004PR], and 60/400,289, filed Jul. 31, 2002 [KON-011PR]. The present application is a continuation-in-part of, and claims priority under 35 U.S.C. §120 to, U.S. Ser. No. 10/350,912, filed Jan. 24, 2003 [KON-004], which, in turn, is a continuation-in-part of U.S. Ser. No. 10/057,394, filed Jan. 25, 2002, now U.S. Pat. No. 6,706,963 [KON-001], and also claims the benefit under 35 U.S.C. §1119 of U.S. Ser. Nos. 60/351,691, filed Jan. 25, 2002 [KON-003PR], 60/368,832 filed Mar. 29, 2002 [KON-004PR], and 60/400,289, filed Jul. 31, 2002 [KON-001PR]. The present application is a continuation-in-part of, and claims priority under 35 U.S.C. §120 to, U.S. Ser. No. 10/350,812, filed Jan. 24, 2003 [KON-005], which, in turn, is a continuation-in-part of U.S. Ser. No. 10/057,394, filed Jan. 25, 2002, now U.S. Pat. No. 6,706,963 [KON-001], and also claims the benefit under 35 U.S.C. §119 of U.S. Ser. Nos. 60/351,691, filed Jan. 25, 2002 [KON-003PR], 60/368,832, filed Mar. 29, 2002 [KON-004PR], 60/390,071, filed Jun. 20, 2002 [KON-006PR], 60/396,173, filed Jul. 16, 2002 [KON-005PR], and 60/400,289, filed Jul. 31, 2002 [KON-011PR]. The present application is a continuation-in-part of, and claims priority under 35 U.S.C. §120 to, U.S. Ser. No. 10/350,800, filed Jan. 24, 2003 [KON-006], which, in turn, is a continuation-in-part of U.S. Ser. No. 10/057,394, filed Jan. 25, 2002, now U.S. Pat. No. 6,706,963 [KON-001], and also claims the benefit under 35 U.S.C. § 19 of U.S. Ser. Nos. 60/390,071, filed Jun. 20, 2002 [KON-006PR], and 60/400,289, filed Jul. 31, 2002 [KON-011PR]. The present application is a continuation-in-part of, and claims priority under 35 U.S.C. §120 to, U.S. Ser. No. 10/351,298, filed Jan. 24, 2003 [KON-007], which, in turn, is a continuation-in-part of U.S. Ser. No. 10/057,394, filed Jan. 25, 2002, now U.S. Pat. No. 6,706,963 [KON-001], and also claims the benefit under 35 U.S.C. §119 of U.S. Ser. Nos. 60/351,691, filed Jan. 25, 2002 [KON-003PR], 60/368,832, filed Mar. 29, 2002 [KON-004PR], 60/400,289, filed Jul. 31, 2002 [KON-001PR], and 60/427,642, filed Nov. 19, 2002 [KON-012PR]. The present application is a continuation-in-part of, and claims priority under 35 U.S.C. §120 to, U.S. Ser. No. 10/351,260, filed Jan. 24, 2003 [KON-008], which, in turn, is a continuation-in-part of U.S. Ser. No. 10/057,394, filed Jan. 25, 2002, now U.S. Pat. No. 6,706,963 [KON-001], and also claims the benefit under 35 U.S.C. §1119 of U.S. Ser. Nos. 60/351,691, filed Jan. 25, 2002 [KON-003PR], 60/368,832, filed Mar. 29, 2002 [KON-004PR], and 60/400,289, filed Jul. 31, 2002 [KON-001PR]. The present application is a continuation-in-part of, and claims priority under 35 U.S.C. §120 to, U.S. Ser. No. 10/351,249, filed Jan. 24, 2003 [KON-009], which claims the benefit under 35 U.S.C. § 119 of U.S. Ser. No. 60/400,289, filed Jul. 31, 2002 [KON-011PR]. The present application is a continuation-in-part of, and claims priority under 35 U.S.C. §120 to, U.S. Ser. No. 10/350,919, filed Jan. 24, 2003 [KON-010], which, in turn, is a continuation-in-part of U.S. Ser. No. 10/057,394, filed Jan. 25, 2002, now U.S. Pat. No. 6,706,963 [KON-001], and also claims the benefit under 35 U.S.C. § 119 of U.S. S. Nos. 60/351,691, filed Jan. 25, 2002 [KON-003PR], 60/368,832, filed Mar. 29, 2002 [KON-004PR], and 60/400,289, filed Jul. 31, 2002 [KON-001PR]. The present application is a continuation-in-part of, and claims priority under 35 U.S.C. §120 to, U.S. Ser. No. 10/351,264, filed Jan. 24, 2003 [KON-011], which claims the benefit under 35 U.S.C. §119 of U.S. Ser. Nos. 60/400,289, filed Jul. 31, 2002 [KON-011PR], and 60/427,642, filed Nov. 19, 2002 [KON-012PR]. The present application is a continuation-in-part of, and claims priority under 35 U.S.C. §120 to, U.S. Ser. No. 10/351,265, filed Jan. 24, 2003 [KON-012], which, in turn, is a continuation-in-part of U.S. Ser. No. 10/057,394, filed Jan. 25, 2002, now U.S. Pat. No. 6,706,963 [KON-001], and also claims the benefit under 35 U.S.C. § 119 of U.S. Ser. Nos. 60/351,691, filed Jan. 25, 2002 [KON-003PR], 60/368,832, filed Mar. 29, 2002 [KON-004PR], 60/427,642, filed Nov. 19, 2002 [KON-012PR], and 60/400,289, filed Jul. 31, 2002 [KON-011PR]. The present application is a continuation-in-part of, and claims priority under 35 U.S.C. §120 to, U.S. Ser. No. 10/351,251, filed Jan. 24, 2003 [KON-013], which, in turn, is a continuation-in-part of U.S. Ser. No. 10/057,394, filed Jan. 25, 2002, now U.S. Pat. No. 6,706,963 [KON-001], and also claims the benefit under 35 U.S.C. § 119 of U.S. Ser. Nos. 60/351,691, filed Jan. 25, 2002 [KON-003PR], 60/368,832, filed Mar. 29, 2002 [KON-004PR], 60/427,642, filed Nov. 19, 2002 [KON-012PR], and 60/400,289, filed Jul. 31, 2002 [KON-011PR]. The present application is a continuation-in-part of, and claims priority under 35 U.S.C. §120 to, U.S. Ser. No. 10/351,250, filed Jan. 24, 2003 [KON-014], which, in turn, is a continuation-in-part of U.S. Ser. No. 10/057,394, filed Jan. 25, 2002, now U.S. Pat. No. 6,706,963 [KON-001], and also claims the benefit under 35 U.S.C. §1119 of U.S. Ser. Nos. 60/351,691, filed Jan. 25, 2002 [KON-003PR], 60/368,832, filed Mar. 29, 2002 [KON-004PR], 60/427,642, filed Nov. 19, 2002 [KON-012PR], and 60/400,289, filed Jul. 31, 2002 [KON-001PR]. The present application is a continuation-in-part of, and claims priority under U.S.C. §120 to, U.S. Ser. No. 10/486,116, filed Feb. 6, 2004 [Q-01], which, in turn, claims priority under 35 U.S.C. §371 to international patent application serial number PCT/AT02/00166, filed May 31, 2002, which, in turn, claims priority to Austrian patent application serial number 1231/2001, filed Aug. 7, 2001. The present application is a continuation-in-part of, and claims priority under U.S.C. §120 to, U.S. Ser. No. 10/494,560, filed May 4, 2004 [KON-025], which, in turn, claims priority under 35 U.S.C. §371 to international patent application serial number PCT/SE02/02049, filed Nov. 8, 2002, which, in turn, claims priority to Swedish patent application serial number 0103740-7, filed Nov. 8, 2001. The present application is a continuation-in-part of, and claims priority under U.S.C. §120 to, U.S. Ser. No. 10/498,484, filed Jun. 14, 2004 [SA-3], which, in turn, claims priority under 35 U.S.C. §371 to international patent application serial number PCT/DE02/04563, filed Feb. 12, 2002, which, in turn, claims priority to German patent application serial number 101 61 303.2, filed Dec. 13, 2001. The present application is a continuation-in-part of, and claims priority under U.S.C. §120 to, U.S. Ser. No. 10/504,091, filed Aug. 1, 2004 [SA-2], which, in turn, claims priority under 35 U.S.C. §371 to international patent application serial number PCT/DE03/00385, filed Feb. 10, 2003, which, in turn, claims priority to German patent application serial number 102 05 579.3, filed Feb. 12, 2002. The present application is a continuation-in-part of, and claims priority under U.S.C. §120 to, U.S. Ser. No. 10/509,935, filed Oct. 1, 2004 [Q-02], which, in turn, claims priority under 35 U.S.C. §371 to international patent application serial number PCT/AT03/00131, filed May 6, 2003, which, in turn, claims priority to Austrian patent application serial number 775/2002, filed May 22, 2002. The present application is a continuation-in-part of, and claims priority under U.S.C. §120 to, U.S. Ser. No. 10/515,159, filed Nov. 19, 2004 [SA-7], which, in turn, claims the benefit under 35 U.S.C. §371 to international patent application serial number PCT/DE03/01867, filed Jun. 5, 2003, which, in turn, claims priority to German patent application serial number 102 26 669.7, filed Jun. 14, 2002. The present application is a continuation-in-part of, and claims priority under 35 U.S.C. §120 to, U.S. Ser. No. 10/723,554, filed Nov. 26, 2003 [KON-018], which, in turn, is a continuation-in-part of 10/395,823, filed Mar. 24, 2003 [KON-015], which, in turn, claims the benefit under 35 U.S.C. § 119 of U.S. Ser. Nos. 60/368,832, filed Mar. 29, 2002, and 60/400,289, filed Jul. 31, 2002. The present application is a continuation-in-part of, and claims priority under U.S.C. §120 to, U.S. Ser. No. 10/897,268, filed Jul. 22, 2004 [KON-016], which, in turn, claims the benefit under 35 U.S.C. §119 of U.S. Ser. No. 60/495,302, filed Aug. 15, 2003. The present application is a continuation-in-part of, and claims priority under U.S.C. §120 to, U.S. Ser. No. 11/000,276, filed Nov. 30, 2004 [KON-017], which, in turn, claims the benefit under 35 U.S.C. § 119 of U.S. Ser. No. 60/526,373, filed Dec. 1, 2003. The present application is a continuation-in-part of, and claims priority under U.S.C. §120 to, U.S. Ser. No. 11/033,217, filed Jan. 10, 2005 [KON-019], which, in turn, claims the benefit under 35 U.S.C. §119 of U.S. Ser. No. 60/546,818, filed Feb. 19, 2004. The present application is a continuation-in-part of, and claims priority under U.S.C. §120 to, U.S. Ser. No. 10/522,862, filed Dec. 31, 2005 [SA-4], which, in turn, claims the benefit under 35 U.S.C. §371 to international patent application serial number PCT/DE03/02463, filed Jul. 22, 2003, which, in turn, claims priority to German patent application serial number 102 36 464.8, filed Aug. 8, 2002.

The present application claims priority under 35 U.S.C. §119 to: U.S. Ser. No. 60/575,971, filed Jun. 1, 2004 [KON-020]; U.S. Ser. No. 60/576,033, filed Jun. 2, 2004 [KON-021]; U.S. Ser. No. 60/589,423, filed Jul. 20, 2004 [KON-023]; U.S. Ser. No. 60/590,312, filed Jul. 22, 2004 [KON-026]; U.S. Ser. Nos. 60/590,313, filed Jul. 22, 2004 [KON-027]; 60/637,844, filed Dec. 20, 2004 [KON-028]; U.S. Ser. No. 60/638,070, filed Dec. 21, 2004 [KON-02960/664,298, filed Mar. 22, 2005 [KON-024]; 60/663,985, filed Mar. 21, 2005 [KON-030]; 60/664,114, filed Mar. 21, 2005 [KON-031]; and 60/664,336, filed Mar. 23, 2005 [KON-24B].] [VERIFY PRIORITY CLAIMS. ADD ANY SEBSEQUENT OR OTHER RELEVANT PRIORITY CLAIMS OR INCORPORATIONS BY REFERENCE].

The contents of these applications are hereby incorporated by reference.

### TECHNICAL FIELD

The invention relates to photovoltaic cells, systems and methods, as well as related compositions, in association with mobile communications facilities.

### BACKGROUND

Photovoltaic cells, sometimes called solar cells, can convert light, such as sunlight, into electrical energy.

One type of photovoltaic cell is commonly referred to as a dye-sensitized solar cell (DSSC). As shown in FIG. 1, a DSSC 100 can include a charge carrier layer 140 (e.g., including an electrolyte, such as an iodide/iodine solution) and a photoactive layer 145 disposed between electrically conductive layers 120 (e.g., an ITO layer or tin oxide layer) and 150 (e.g., an ITO layer or tin oxide layer). Photoactive layer 145 typically includes a semiconductor material, such as TiO₂ particles, and a photosensitizing agent, such as a dye. In general, the photosensitizing agent is capable of absorbing photons within a wavelength range of operation (e.g., within the solar spectrum). DSSC 100 also includes a substrate 160 (e.g., a glass or polymer substrate) and a substrate 110 (e.g., a glass or polymer substrate). Electrically conductive layer 150 is disposed on an inner surface 162 of substrate 160, and electrically conductive layer 120 is disposed on an inner surface 112 of substrate 110. DSSC 100 further includes a catalyst 130 (e.g., formed of platinum), which can catalyze a redox reaction in charge carrier layer 140. Catalyst layer 130 is typically disposed on a surface 122 of electrically conductive layer 120. Electrically conductive layers 120 and 150 are electrically connected across an external electrical load 170.

During operation, in response to illumination by radiation in the solar spectrum, DSSC 100 can undergo cycles of excitation, oxidation, and reduction that produce a flow of electrons across load 170. Incident light can excite photosensitizing agent molecules in photoactive layer 145. The photoexcited photosensitizing agent molecules can then inject electrons into the conduction band of the semiconductor in layer 145, which can leave the photosensitizing agent molecules oxidized. The injected electrons can flow through the semiconductor material, to electrically conductive layer 150, then to external load 170. After flowing through external load 170, the electrons can flow to layer 120, then to layer 130 and subsequently to layer 140, where the electrons can reduce the electrolyte material in charge carrier layer 140 at catalyst layer 130. The reduced electrolyte can then reduce the oxidized photosensitizing agent molecules back to their neutral state. The electrolyte in layer 140 can act as a redox mediator to control the flow of electrons from layer 120 to layer 150. This cycle of excitation, oxidation, and reduction can be repeated to provide continuous electrical energy to external load 170.

Another type of photovoltaic cell is commonly referred to a polymer photovoltaic cell. As shown in FIG. 2, a polymer photovoltaic cell 200 can include a first substrate 210 (e.g., a glass or polymer substrate), a first electrically conductive layer 220 (e.g., an ITO layer or tin oxide layer), a hole blocking layer 230 (e.g., a lithium fluoride or metal oxide layer), a photoactive layer 240, a hole carrier layer 250 (e.g., a polymer layer), a second electrically conductive layer 260 (e.g., an ITO layer or tin oxide layer), and a second substrate 270 (e.g., a glass or polymer substrate).

Light can interact with photoactive layer 240, which generally includes an electron donor material (e.g., a polymer) and an electron acceptor material (e.g., a fullerene). Electrons can be transferred from the electron donor material to the electron acceptor material. The electron acceptor material in layer 240 can transmit the electrons through hole blocking layer 230 to electrically conductive layer 220. The electron donor material in layer 240 can transfer holes through hole carrier layer 250 to electrically conductive layer 260. First and second electrically conductive layers 220 and 260 are electrically connected across an external load 280 so that electrons pass from electrically conductive layer 260 to electrically conductive layer 220.

### SUMMARY

The invention relates to photovoltaic cells, facilities, systems and methods, as well as related compositions. An aspect of the present invention relates to associating photovoltaic facilities, in various forms, with mobile communication facilities.

A mobile communication facility may be associated with a flexible photovoltaic facility. The flexible photovoltaic facility may be adapted to conform to at least a portion of the outer surface of the mobile communication facility. The flexible photovoltaic facility may comprise a mesh and may have plastic-like, cloth-like and/or fabric-like properties. The flexible photovoltaic facility may be composed of at least one photovoltaic fiber. The photovoltaic facility may be printed onto the mobile communication facility.

The mobile communication facility may be a handheld and/or portable communication facility. The mobile communication facility may be a cell phone, a satellite phone, a cordless phone, a cordless phone handset, a personal digital assistant, a palmtop computer, a laptop computer, a computing device, a transponder, a pager and/or a walkie talkie. The flexible photovoltaic facility may directly power the mobile communication facility. The flexible photovoltaic facility may also be associated with an energy storage facility for storing energy generated by the photovoltaic facility.

The flexible photovoltaic facility may be aesthetically customized and create or have a distinct appearance. The photovoltaic facility may absorb or transmit light with selected properties.

A mobile communication facility may be associated with a photovoltaic face plate which may snap or click onto the mobile communication facility. The face plate may be interchanged among mobile communication facilities. The photovoltaic face plate may be flexible. The photovoltaic face plate may comprise a mesh and may have plastic-like, cloth-like and/or fabric-like properties. The photovoltaic face plate may be composed of at least one photovoltaic fiber. The face plate may act as a protective covering for the mobile communication facility.

The photovoltaic face plate may be aesthetically customized with a distinct appearance created by the certain properties of the photovoltaic facility. The associated photovoltaic facility or facilities may absorb or transmit light with selected properties.

The photovoltaic face plate may directly power the mobile communication facility. In embodiments, the photovoltaic face plate may also be associated with an energy storage facility for storing energy generated by the photovoltaic face plate.

A mobile communication facility may be associated with a photovoltaic skin. The photovoltaic skin may cover the entire surface of the mobile communication facility or only a portion of the surface of the mobile communication facility. The photovoltaic skin may be flexible.

The photovoltaic skin may directly power the mobile communication facility. The photovoltaic skin may also be associated with an energy storage facility for storing energy generated by the photovoltaic facility.

The photovoltaic skin may be flexible and formed to the mobile communication facility. The photovoltaic skin may act as a protective covering for the mobile communication facility.

The photovoltaic skin may be aesthetically customized and may create or have a distinct appearance.

The photovoltaic skin may be associated with the mobile communication facility during manufacturing or may be applied to the mobile communication facility after manufacturing.

Features and advantages of the invention are in the description, drawings and claims.

### BRIEF DESCRIPTION OF DRAWINGS

FIG. 1 is a cross-sectional view of an embodiment of a DSSC.

FIG. 2 is a cross-sectional view of an embodiment of a polymer photovoltaic cell.

FIG. 3 is a cross-sectional view of an embodiment of a DSSC.

FIG. 4 illustrates a method of making a DSSC.

FIG. 5 is a schematic view of a module containing multiple photovoltaic cells.

FIG. 6 is a schematic view of a module containing multiple photovoltaic cells.

FIG. 7 is a cross-sectional view of an embodiment of a polymer photovoltaic cell.

FIG. 8 is a cross-sectional view of an embodiment of a photovoltaic fiber.

FIG. 9 depicts an embodiment of a photovoltaic material that includes a fiber, one or more wires, a photosensitized nanomatrix material and a charge carrier material.

FIG. 10 depicts an embodiment of a method of forming a photovoltaic material that has an electrically conductive fiber core, a light transmitting electrical conductor and a photoconversion material.

FIG. 11 depicts an embodiment of a photovoltaic material formed by wrapping a platinum or platinized wire around a core including a photoconversion material.

FIG. 12A depicts an embodiment of a photovoltaic material that includes a metal-textile fiber.

FIG. 12B depicts an embodiment of a photovoltaic material that includes a metal-textile fiber with a dispersion of titanium dioxide nanoparticles coated on the outer surface.

FIG. 12C depicts an embodiment of a photovoltaic material that includes a metal-textile fiber with a dispersion of titanium dioxide nanoparticles coated on the outer surface and a charge carrier material.

FIG. 13 depicts an embodiment of a photovoltaic fabric.

FIG. 14 depicts an embodiment of a photovoltaic fabric formed by a two-component photovoltaic material.

FIG. 15 illustrates a photovoltaic communication facility according to the principles of the present invention.

FIG. 16 illustrates a photovoltaic communication facility in the presence of sunlight according to the principles of the present invention.

FIG. 17 illustrates a photovoltaic communication facility in the presence of artificial light according to the principles of the present invention.

FIG. 18 illustrates a photovoltaic communication facility including a photovoltaic facility, a communication facility, and an energy storage facility according to the principles of the present invention.

FIG. 19 illustrates a photovoltaic communication facility including a photovoltaic facility, a communication facility, and an energy filtering facility according to the principles of the present invention.

FIG. 20 illustrates a photovoltaic communication facility including a photovoltaic facility, a communication facility, and an energy regulation facility according to the principles of the present invention.

FIG. 21 illustrates a photovoltaic communication facility including a photovoltaic facility, a communication facility, an energy storage facility, and a recharging facility according to the principles of the present invention.

FIG. 22 illustrates a photovoltaic communication facility including a photovoltaic facility, a communication facility, a processing facility, a receiving facility, a transmitting facility, and a memory facility according to the principles of the present invention.

FIG. 23 illustrates a photovoltaic communication facility including a photovoltaic facility, a communication facility, and an MEMS facility according to the principles of the present invention.

FIG. 24 illustrates a photovoltaic communication facility network according to the principles of the present invention.

FIG. 25 illustrates a photovoltaic communication facility network according to the principles of the present invention.

FIG. 26 illustrates a photovoltaic communication facility network according to the principles of the present invention.

FIG. 27 illustrates a photovoltaic communication facility network according to the principles of the present invention.

FIG. 28 illustrates a photovoltaic communication facility peer-to-peer network according to the principles of the present invention.

FIG. 29 illustrates a photovoltaic communication facility network wherein the communication between devices involves the internet according to the principles of the present invention.

FIG. 30 illustrates a photovoltaic communication facility array in communication with a network according to the principles of the present invention.

FIG. 31 illustrates several photovoltaic communication facilities arranged on a communication network wherein the network of communication facilities is in communication with a computer network according to the principles of the present invention.

FIG. 32 illustrates several variable photovoltaic structures according to the principles of the present invention.

FIG. 33 illustrates a variable photovoltaic structure wherein the variable photovoltaic structure includes multiple photovoltaic segments connected through electrical segments which can rotate or be rotated according to the principles of the present invention.

FIG. 34 illustrates another variable photovoltaic structure wherein the variable photovoltaic structure includes multiple photovoltaic segments connected through foldable electrical segments according to the principles of the present invention.

FIG. 35 illustrates another variable photovoltaic structure wherein the variable photovoltaic structure includes multiple photovoltaic segments connected through foldable electrical segments according to the principles of the present invention.

FIG. 36 illustrates several variable photovoltaic structures according to the principles of the present invention.

FIG. 37 illustrates a variable photovoltaic structure with eight foldable segments according to the principles of the present invention.

FIG. 38 illustrates several variable photovoltaic structures according to the principles of the present invention according to the principles of the present invention.

FIG. 39 illustrates a variable photovoltaic structure adapted to sense light and position itself in relation to the light in accordance with the principles of the present invention according to the principles of the present invention.

FIG. 40 illustrates a mobile communication facility in association with a flexible photovoltaic facility.

FIG. 41 illustrates a mobile communication facility in association with a photovoltaic face plate.

FIG. 42 illustrates a mobile communication facility in association with a photovoltaic skin.

### DETAILED DESCRIPTION

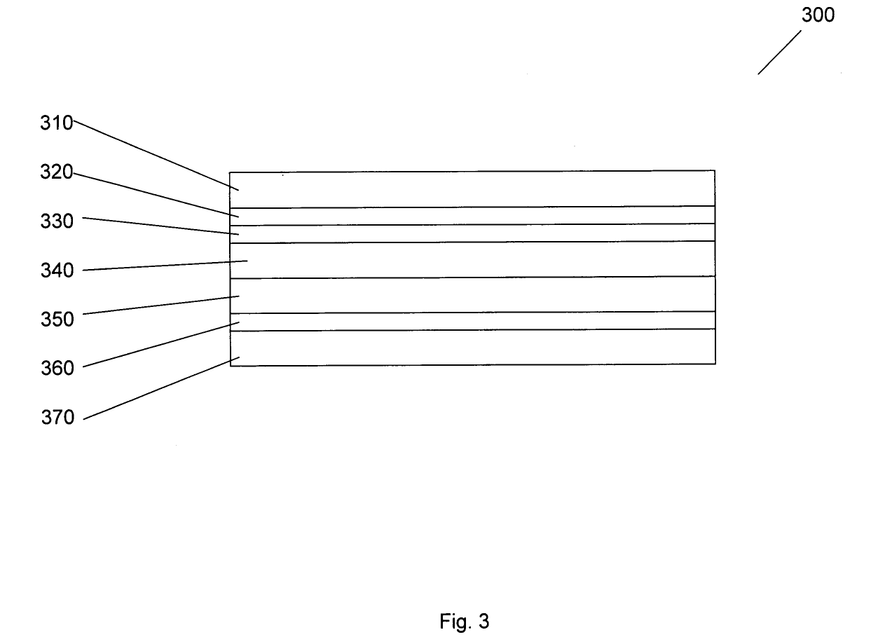

FIG. 3 is a cross-sectional view of a DSSC 300 including substrates 310 and 370, electrically conductive layers 320 and 360, a catalyst layer 330, a charge carrier layer 340, and a photoactive layer 350.

Photoactive layer 350 generally includes one or more dyes and a semiconductor material associated with the dye.

Examples of dyes include black dyes (e.g., tris(isothiocyanato)-ruthenium (II)-2,2′:6′,2″-terpyridine-4,4′,4″-tricarboxylic acid, tris-tetrabutylammonium salt), orange dyes (e.g., tris(2,2′-bipyridyl-4,4′-dicarboxylato) ruthenium (II) dichloride, purple dyes (e.g., cis-bis(isothiocyanato)bis-(2,2′-bipyridyl-4,4′-dicarboxylato)-ruthenium (II)), red dyes (e.g., an eosin), green dyes (e.g., a merocyanine) and blue dyes (e.g., a cyanine). Examples of additional dyes include anthocyanines, porphyrins, phthalocyanines, squarates, and certain metal-containing dyes.

In some embodiments, photoactive layer 350 can include multiple different dyes that form a pattern. Examples of patterns include camouflage patterns, roof tile patterns and shingle patterns. In some embodiments, the pattern can define the pattern of the housing a portable electronic device (e.g., a laptop computer, a cell phone). In certain embodiments, the pattern provided by the photovoltaic cell can define the pattern on the body of an automobile. Patterned photovoltaic cells are disclosed, for example, in co-pending and commonly owned U.S. Ser. No. 60/638,070, filed Dec. 21, 2004 [KON-029], which is hereby incorporated by reference.

Examples of semiconductor materials include materials having the formula MₓO_{y} where M may be, for example, titanium, zirconium, tungsten, niobium, lanthanum, tantalum, terbium, or tin and x and y are integers greater than zero. Other suitable materials include sulfides, selenides, tellurides, and oxides of titanium, zirconium, tungsten, niobium, lanthanum, tantalum, terbium, tin, or combinations thereof. For example, TiO₂, SrTiO₃, CaTiO₃, ZrO₂, WO₃, La₂O₃, Nb₂O₅, SnO₂, sodium titanate, cadmium selenide (CdSe), cadmium sulphides, and potassium niobate may be suitable materials.

Typically, the semiconductor material contained within layer 350 is in the form of nanoparticles. In some embodiments, the nanoparticles have an average size between about two nm and about 100 nm (e.g., between about 10 nm and 40 nm, such as about 20 nm). Examples of nanoparticle semiconductor materials are disclosed, for example, in co-pending and commonly owned U.S. Ser. No. 10/351,249 [KON-009], which is hereby incorporated by reference.

The nanoparticles can be interconnected, for example, by high temperature sintering, or by a reactive linking agent.

In certain embodiments, the linking agent can be a non-polymeric compound. The linking agent can exhibit similar electronic conductivity as the semiconductor particles. For example, for TiO₂ particles, the agent can include Ti—O bonds, such as those present in titanium alkoxides. Without wishing to be bound by theory, it is believed that titanium tetraalkoxide particles can react with each other, with TiO₂ particles, and with a conductive coating on a substrate, to form titanium oxide bridges that connect the particles with each other and with the conductive coating (not shown). As a result, the cross-linking agent enhances the stability and integrity of the semiconductor layer. The cross-linking agent can include, for example, an organometallic species such as a metal alkoxide, a metal acetate, or a metal halide. In some embodiments, the cross-linking agent can include a different metal than the metal in the semiconductor. In an exemplary cross-linking step, a cross-linking agent solution is prepared by mixing a sol-gel precursor agent, e.g., a titanium tetra-alkoxide such as titanium tetrabutoxide, with a solvent, such as ethanol, propanol, butanol, or higher primary, secondary, or tertiary alcohols, in a weight ratio of 0-100%, e.g., about 5 to about 25%, or about 20%. Generally, the solvent can be any material that is stable with respect to the precursor agent, e.g., does not react with the agent to form metal oxides (e.g. TiO₂). The solvent preferably is substantially free of water, which can cause precipitation of TiO₂. Such linking agents are disclosed, for example, in published U.S. Patent Application 2003-0056821 [UMASS application], which is hereby incorporated by reference.

In some embodiments, a linking agent can be a polymeric linking agent, such as poly (n-butyl) titanate. Examples of polymeric linking agents are disclosed, for example, in co-pending and commonly owned U.S. Ser. No. 10/350,913 [KON-003], which is hereby incorporated by reference.

Linking agents can allow for the fabrication of an interconnected nanoparticle layer at relatively low temperatures (e.g., less than about 300° C.) and in some embodiments at room temperature. The relatively low temperature interconnection process may be amenable to continuous (e.g., roll-to-roll) manufacturing processes using polymer substrates.

The interconnected nanoparticles are generally photosensitized by the dye(s). The dyes facilitate conversion of incident light into electricity to produce the desired photovoltaic effect. It is believed that a dye absorbs incident light resulting in the excitation of electrons in the dye. The energy of the excited electrons is then transferred from the excitation levels of the dye into a conduction band of the interconnected nanoparticles. This electron transfer results in an effective separation of charge and the desired photovoltaic effect. Accordingly, the electrons in the conduction band of the interconnected nanoparticles are made available to drive an external load.

The dye(s) can be sorbed (e.g., chemisorbed and/or physisorbed) on the nanoparticles. A dye can be selected, for example, based on its ability to absorb photons in a wavelength range of operation (e.g., within the visible spectrum), its ability to produce free electrons (or electron holes) in a conduction band of the nanoparticles, its effectiveness in complexing with or sorbing to the nanoparticles, and/or its color.

In some embodiments, photoactive layer 350 can further include one or more co-sensitizers that adsorb with a sensitizing dye to the surface of an interconnected semiconductor oxide nanoparticle material, which can increase the efficiency of a DSSC (e.g., by improving charge transfer efficiency and/or reducing back transfer of electrons from the interconnected semiconductor oxide nanoparticle material to the sensitizing dye). The sensitizing dye and the co-sensitizer may be added together or separately when forming the photosensitized interconnected nanoparticle material. The co-sensitizer can donate electrons to an acceptor to form stable cation radicals, which can enhance the efficiency of charge transfer from the sensitizing dye to the semiconductor oxide nanoparticle material and/or can reduce back electron transfer to the sensitizing dye or co-sensitizer. The co-sensitizer can include (1) conjugation of the free electron pair on a nitrogen atom with the hybridized orbitals of the aromatic rings to which the nitrogen atom is bonded and, subsequent to electron transfer, the resulting resonance stabilization of the cation radicals by these hybridized orbitals; and/or (2) a coordinating group, such as a carboxy or a phosphate, the function of which is to anchor the co-sensitizer to the semiconductor oxide. Examples of suitable co-sensitizers include aromatic amines (e.g., color such as triphenylamine and its derivatives), carbazoles, and other fused-ring analogues. Examples of photoactive layers including co-sensitizers are disclosed, for example, in co-pending and commonly owned U.S. Ser. No. 10/350,919 [KON-010], which is hereby incorporated by reference.

In some embodiments, photoactive layer 350 can further include macroparticles of the semiconductor material, where at least some of the semiconductor macroparticles are chemically bonded to each other, and at least some of the semiconductor nanoparticles are bonded to semiconductor macroparticles. The dye(s) are sorbed (e.g., chemisorbed and/or physisorbed) on the semiconductor material. Macroparticles refers to a collection of particles having an average particle size of at least about 100 nanometers (e.g., at least about 150 nanometers, at least about 200 nanometers, at least about 250 nanometers). Examples of photovoltaic cells including macroparticles in the photoactive layer are disclosed, for example, in co-pending and commonly owned U.S. Ser. No. 60/589,423 [KON-023], which is hereby incorporated by reference.

In certain embodiments, a DSSC can include a coating that can enhance the adhesion of a photovoltaic material to a base material (e.g., using relatively low process temperatures, such as less than about 300° C.). Such photovoltaic cells and methods are disclosed, for example, in co-pending and commonly owned U.S. Ser. No. 10/351,260 [KON-008], which is hereby incorporated by reference.

The composition and thickness of electrically conductive layer 320 is generally selected based on desired electrical conductivity, optical properties, and/or mechanical properties of the layer. In some embodiments, layer 320 is transparent. Examples of transparent materials suitable for forming such a layer include certain metal oxides, such as indium tin oxide (ITO), tin oxide, and a fluorine-doped tin oxide. In some embodiments, electrically conductive layer 320 can be formed of a foil (e.g., a titanium foil). Electrically conductive layer 320 may be, for example, between about 100 nm and 500 nm thick, (e.g., between about 150 nm and 300 nm thick).

In certain embodiments, electrically conductive layer 320 can be opaque (i.e., can transmit less than about 10% of the visible spectrum energy incident thereon). For example, layer 320 can be formed from a continuous layer of an opaque metal, such as copper, aluminum, indium, or gold. In some embodiments, an electrically conductive layer can have an interconnected nanoparticle material formed thereon. Such layers can be, for example, in the form of strips (e.g., having a controlled size and relative spacing, between first and second flexible substrates). Examples of such DSSCs are disclosed, for example, in co-pending and commonly owned U.S. Ser. No. 10/351,251 [KON-013], which is hereby incorporated by reference.

In some embodiments, electrically conductive layer 320 can include a discontinuous layer of a conductive material. For example, electrically conductive layer 320 can include an electrically conducting mesh. Suitable mesh materials include metals, such as palladium, titanium, platinum, stainless steels and alloys thereof. In some embodiments, the mesh material includes a metal wire. The electrically conductive mesh material can also include an electrically insulating material that has been coated with an electrically conducting material, such as a metal. The electrically insulating material can include a fiber, such as a textile fiber or monofilament. Examples of fibers include synthetic polymeric fibers (e.g., nylons) and natural fibers (e.g., flax, cotton, wool, and silk). The mesh electrically conductive layer can be flexible to facilitate, for example, formation of the DSSC by a continuous manufacturing process. Photovoltaic cells having mesh electrically conductive layers are disclosed, for example, in co-pending and commonly owned U.S. Ser. Nos. 10/395,823; 10/723,554 and 10/494,560 [KON-015, KON-018 and KON-025, respectively], each of which is hereby incorporated by reference.

The mesh electrically conductive layer may take a wide variety of forms with respect to, for example, wire (or fiber) diameters and mesh densities (i.e., the number of wires (or fibers) per unit area of the mesh). The mesh can be, for example, regular or irregular, with any number of opening shapes. Mesh form factors (such as, e.g., wire diameter and mesh density) can be chosen, for example, based on the conductivity of the wire (or fibers) of the mesh, the desired optical transmissivity, flexibility, and/or mechanical strength. Typically, the mesh electrically conductive layer includes a wire (or fiber) mesh with an average wire (or fiber) diameter in the range from about one micron to about 400 microns, and an average open area between wires (or fibers) in the range from about 60% to about 95%.

Catalyst layer 330 is generally formed of a material that can catalyze a redox reaction in the charge carrier layer positioned below. Examples of materials from which catalyst layer can be formed include platinum and polymers, such as polythiophenes, polypyrroles, polyanilines and their derivatives. Examples of polythiophene derivatives include poly(3,4-ethylenedioxythiophene) (“PEDOT”), poly(3-butylthiophene), poly[3-(4-octylphenyl)thiophene], poly(thieno[3,4-b]thiophene) (“PT34bT”), and poly(thieno[3,4-b]thiophene-co-3,4-ethylenedioxythiophene) (“PT34bT-PEDOT”). Examples of catalyst layers containing one or more polymers are disclosed, for example, in co-pending and commonly owned U.S. Ser. Nos. 10/897,268 and 60/637,844 [KON-016 and KON-028], both of which are hereby incorporated by reference.

Substrate 310 can be formed from a mechanically-flexible material, such as a flexible polymer, or a rigid material, such as a glass. Examples of polymers that can be used to form a flexible substrate include polyethylene naphthalates (PEN), polyethylene terephthalates (PET), polyethyelenes, polypropylenes, polyamides, polymethylmethacrylate, polycarbonate, and/or polyurethanes. Flexible substrates can facilitate continuous manufacturing processes such as web-based coating and lamination. However, rigid substrate materials may also be used, such as disclosed, for example, in co-pending and commonly owned U.S. Ser. No. 10/351,265 [KON-012], which is hereby incorporated by reference.

The thickness of substrate 310 can vary as desired. Typically, substrate thickness and type are selected to provide mechanical support sufficient for the DSSC to withstand the rigors of manufacturing, deployment, and use. Substrate 310 can have a thickness of from about six microns to about 5,000 microns (e.g., from about 6 microns to about 50 microns, from about 50 microns to about 5,000 microns, from about 100 microns to about 1,000 microns). In embodiments where electrically conductive layer 320 is transparent, substrate 310 is formed from a transparent material. For example, substrate 310 can be formed from a transparent glass or polymer, such as a silica-based glass or a polymer, such as those listed above. In such embodiments, electrically conductive layer 320 may also be transparent.

Substrate 370 and electrically conductive layer 360 can be as described above regarding substrate 310 and electrically conductive layer 320, respectively. For example, substrate 370 can be formed from the same materials and can have the same thickness as substrate 310. In some embodiments however, it may be desirable for substrate 370 to be different from 310 in one or more aspects. For example, where the DSSC is manufactured using a process that places different stresses on the different substrates, it may be desirable for substrate 370 to be more or less mechanically robust than substrate 310. Accordingly, substrate 370 may be formed from a different material, or may have a different thickness than substrate 310. Furthermore, in embodiments where only one substrate is exposed to an illumination source during use, it is not necessary for both substrates and/or electrically conducting layers to be transparent. Accordingly, one of substrates and/or corresponding electrically conducting layer can be opaque.

Generally, charge carrier layer 340 includes a material that facilitates the transfer of electrical charge from a ground potential or a current source to photoactive layer 350. A general class of suitable charge carrier materials include solvent-based liquid electrolytes, polyelectrolytes, polymeric electrolytes, solid electrolytes, n-type and p-type transporting materials (e.g., conducting polymers) and gel electrolytes. Examples of gel electrolytes are disclosed, for example, in co-pending and commonly owned U.S. Ser. No. 10/350,912 [KON-004], which is hereby incorporated by reference. Other choices for charge carrier media are possible. For example, the charge carrier layer can include a lithium salt that has the formula LiX, where X is an iodide, bromide, chloride, perchlorate, thiocyanate, trifluoromethyl sulfonate, or hexafluorophosphate.

The charge carrier media typically includes a redox system. Suitable redox systems may include organic and/or inorganic redox systems. Examples of such systems include cerium(III) sulphate/cerium(IV), sodium bromide/bromine, lithium iodide/iodine, Fe²⁺/Fe³⁺, Co²⁺/Co³⁺, and viologens. Furthermore, an electrolyte solution may have the formula MᵢXⱼ, where i and j are greater than or equal to one, where X is an anion, and M is lithium, copper, barium, zinc, nickel, a lanthanide, cobalt, calcium, aluminum, or magnesium. Suitable anions include chloride, perchlorate, thiocyanate, trifluoromethyl sulfonate, and hexafluorophosphate.

In some embodiments, the charge carrier media includes a polymeric electrolyte. For example, the polymeric electrolyte can include poly(vinyl imidazolium halide) and lithium iodide and/or polyvinyl pyridinium salts. In embodiments, the charge carrier media can include a solid electrolyte, such as lithium iodide, pyridimum iodide, and/or substituted imidazolium iodide.

The charge carrier media can include various types of polymeric polyelectrolytes. For example, suitable polyelectrolytes can include between about 5% and about 95% (e.g., 5-60%, 5-40%, or 5-20%) by weight of a polymer, e.g., an ion-conducting polymer, and about 5% to about 95% (e.g., about 35-95%, 60-95%, or 80-95%) by weight of a plasticizer, about 0.05 M to about 10 M of a redox electrolyte of organic or inorganic iodides (e.g., about 0.05-2 M, 0.05-1 M, or 0.05-0.5 M), and about 0.01 M to about 1 M (e.g., about 0.05-0.5 M, 0.05-0.2 M, or 0.05-0.1 M) of iodine. The ion-conducting polymer may include, for example, polyethylene oxide (PEO), polyacrylonitrile (PAN), polymethylmethacrylate (PMMA), polyethers, and polyphenols. Examples of suitable plasticizers include ethyl carbonate, propylene carbonate, mixtures of carbonates, organic phosphates, butyrolactone, and dialkylphthalates.

In some embodiments, charge carrier layer 340 can include one or more zwitterionic compounds. In general, the zwitterionic compound(s) have the formula: 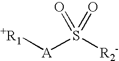
R₁ is a cationic heterocyclic moiety, a cationic ammonium moiety, a cationic guanidinium moiety, or a cationic phosphonium moiety. R₁ can be unsubstituted or substituted (e.g., alkyl substituted, alkoxy substituted, poly(ethyleneoxy) substituted, nitrogen-substituted). Examples of cationic substituted heterocyclic moieties include cationic nitrogen-substituted heterocyclic moieties (e.g., alkyl imidazolium, piperidinium, pyridinium, morpholinium, pyrimidinium, pyridazinium, pyrazinium, pyrazolium, pyrrolinium, thiazolium, oxazolium, triazolium). Examples of cationic substituted ammonium moieties include cationic alkyl substituted ammonium moieties (e.g., symmetric tetraalkylammonium). Examples of cationic substituted guanidinium moieties include cationic alkyl substituted guanidinium moieties (e.g., pentalkyl guanidinium. R₂ is an anoinic moiety that can be: 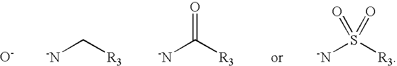
where R₃ is H or a carbon-containing moiety selected from Cₓ alkyl, Cₓ₊₁ alkenyl, Cₓ₊₁ alkynyl, cycloalkyl, heterocyclyl and aryl; and x is at least 1 (e.g., two, three, four, five, six, seven, eight, nine, 10, 11, 12, 13, 14, 15, 16, 17, 18, 19, 20). In some embodiments, a carbon-containing moiety can be substituted (e.g., halo substituted). A is (C(R₃)₂)ₙ, where: n is zero or greater (e.g., one, two, three, four, five, six, seven, eight, nine, 10, 11, 12, 13, 14, 15, 16, 17, 18, 19, 20); and each R₃ is independently as described above. Charge carrier layers including one or more zwitterionic compounds are disclosed, for example, in co-pending and commonly owned U.S. Ser. No. 11/000,276 [KON-017], which is hereby incorporated by reference.

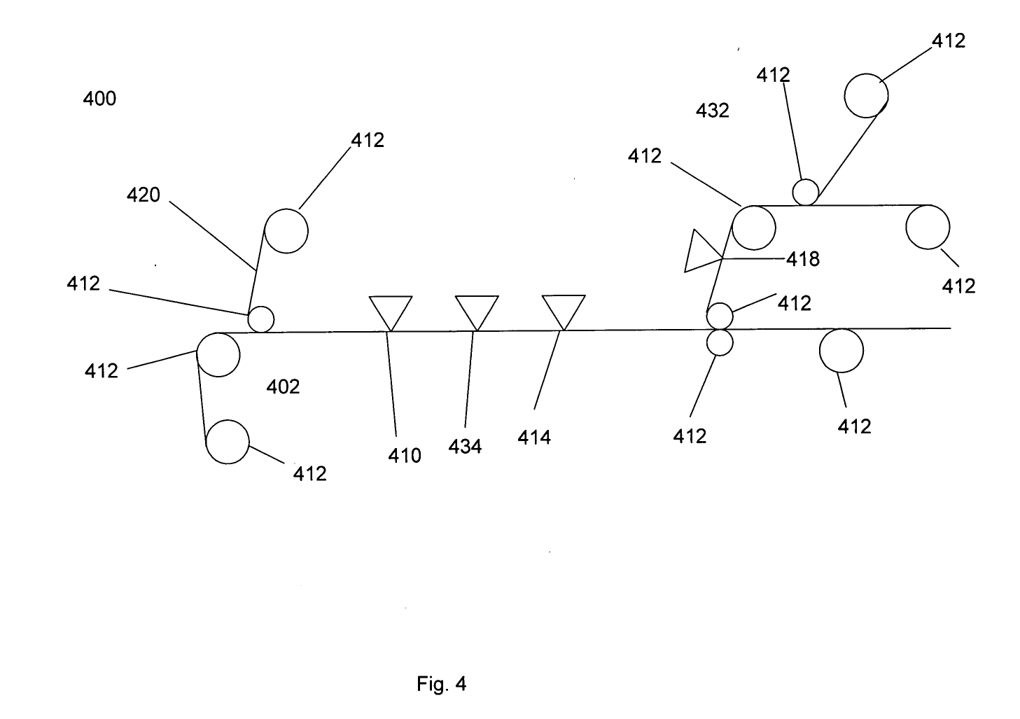

FIG. 4 shows a process (a roll-to-roll process) 400 for manufacturing a DSSC by advancing a substrate 402 between rollers 412. Substrate 402 can be advanced between rollers 430 continuously, periodically, or irregularly during a manufacturing run.

An electrically conductive layer 420 (e.g., a titanium foil) is attached to substrate 402 adjacent location 428.

An interconnected nanoparticle material is then formed on the electrically conductive layer adjacent location 410. The interconnected nanoparticle material can be formed by applying a solution containing a linking agent (e.g., polymeric linking agent, such as poly(n-butyl titanate)) and metal oxide nanoparticles (e.g., titania). In some embodiments, the polymeric linking agent and the metal oxide nanoparticles are separately applied to form the interconnected nanoparticle material. The polymeric linking agent and metal oxide nanoparticles can be heated (e.g., in an oven present in the system used in the roll-to-roll process) to form the interconnected nanoparticle material.

One or more dyes are then applied (e.g., using silk screening, ink jet printing, or gravure printing) to the interconnected nanoparticle material adjacent location 434 to form a photoactive layer.

A charge carrier layer is deposited onto the patterned photoactive layer adjacent location 414. The charge carrier layer can be deposited using known techniques, such as those noted above.

An electrically conductive layer 422 (e.g., ITO) is attached to substrate 424 adjacent location 432.

A catalyst layer precursor is deposited on electrically conductive layer 422 adjacent location 418. The catalyst layer precursor can be deposited on electrically conductive layer 422 using, for example, electrochemical deposition using chloroplatinic acid in an electrochemical cell, or pyrolysis of a coating containing a platinum compound (e.g., chloroplatinic acid). In general, the catalyst layer precursor can be deposited using known coating techniques, such as spin coating, dip coating, knife coating, bar coating, spray coating, roller coating, slot coating, gravure coating, screen coating, and/or ink jet printing. The catalyst layer precursor is then heated (e.g., in an oven present in the system used in the roll-to-roll process) to form the catalyst layer. In some embodiments, electrically conductive material 360 can be at least partially coated with the catalyst layer before attaching to advancing substrate 424. In certain embodiments, the catalyst layer is applied directly to electrically conductive layer 422 (e.g., without the presence of a precursor).

In some embodiments, the method can include scoring the coating of a first coated base material at a temperature sufficiently elevated to part the coating and melt at least a portion of the first base material, and/or scoring a coating of a second coated base material at a temperature sufficiently elevated to part the coating and at least a portion of the second base material, and optionally joining the first and second base materials to form a photovoltaic module. DSSCs with metal foil and methods for the manufacture are disclosed, for example, in co-pending and commonly owned U.S. Ser. No. 10/351,264 [KON-011], which is hereby incorporated by reference.

In certain embodiments, the method can include slitting (e.g., ultrasonic slitting) to cut and/or seal edges of photovoltaic cells and/or modules (e.g., to encapsulate the photoactive components in an environment substantially impervious to the atmosphere). Examples of such methods are disclosed, for example, in co-pending and commonly owned U.S. Ser. No. 10/351,250 [KON-014], which is hereby incorporated by reference.

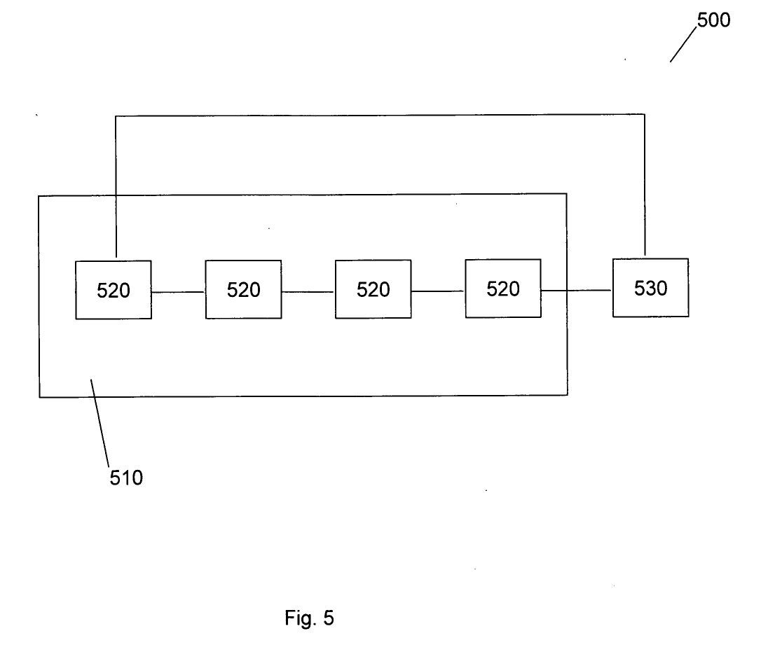

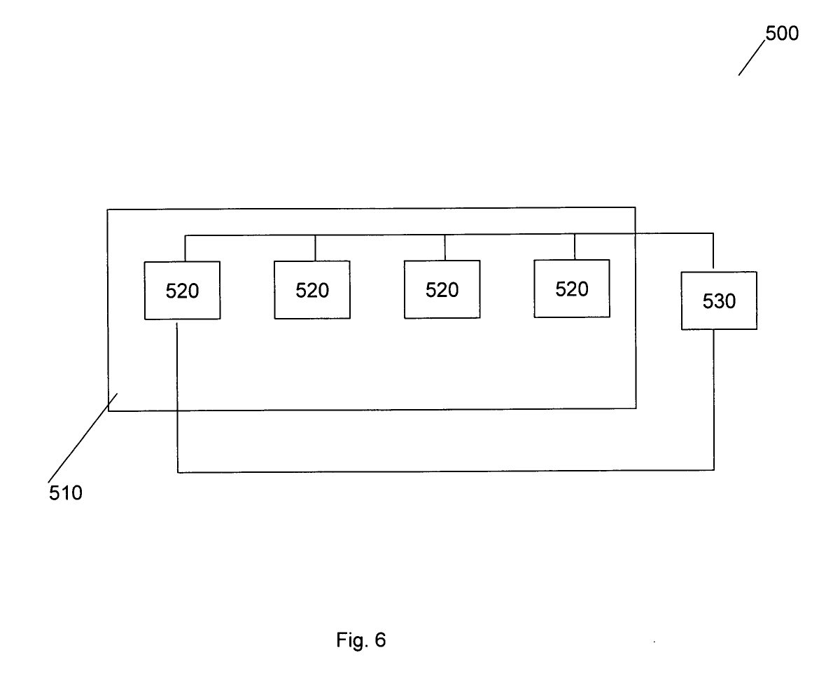

In general, multiple photovoltaic cells can be electrically connected to form a photovoltaic system. As an example, FIG. 5 is a schematic of a photovoltaic system 500 having a module 510 containing photovoltaic cells 520. Cells 520 are electrically connected in series, and system 500 is electrically connected to a load 530. As another example, FIG. 6 is a schematic of a photovoltaic system 500 having a module 510 that contains photovoltaic cells 520. Cells 520 are electrically connected in parallel, and system 500 is electrically connected to a load 530. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel. In certain embodiments, adjacent cell can be in electrical contact via a wire. Photovoltaic modules having such architectures are disclosed, for example, in co-pending and commonly owned U.S. Ser. No. 10/351,298 [KON-007], which is hereby incorporated by reference. In some embodiments, adjacent cells can be in electrical contact via a conductive interconnect (e.g., a stitch) that is disposed in an electrically conductive layer in each of the adjacent cells. Photovoltaic modules having such architecture are disclosed, for example, in co-pending and commonly owned U.S. Ser. No. 60/575,971 [KON-020], which is hereby incorporated by reference. In certain embodiments, adjacent cells can be electrically connected by disposing a shaped (e.g., dimpled, embossed) portion in an electrically conductive layer of one of the cells, where the shaped portion extends through an adhesive and makes electrical contact with an electrically conductive layer in an adjacent cell. With this arrangement, the cells can be in electrical contact without using a separate interconnect component. Photovoltaic modules having such architecture are disclosed, for example, in co-pending and commonly owned U.S. Ser. No. 60/590,312 [KON-026], which is hereby incorporated by reference. In some embodiments, adjacent cells can be electrically connected via an adhesive material and a mesh partially disposed in the adhesive material. Photovoltaic modules having such architecture are disclosed, for example, in co-pending and commonly owned U.S. Ser. No. 60/590,313 [KON-027], which is hereby incorporated by reference. In certain embodiments, a first group of photovoltaic modules are formed on a first region of a substrate, while a second group of photovoltaic modules are formed on a second region of the same substrate. The substrate may then be physically divided, or in some embodiments folded, to combine the respective photovoltaic module portions to produce a final photovoltaic module. The interconnections between the photovoltaic cells of the final module can be parallel, serial, or a combination thereof. Photovoltaic cells having such architecture are disclosed, for example, in U.S. Pat. No. 6,706,963 [KON-001], which is hereby incorporated by reference.

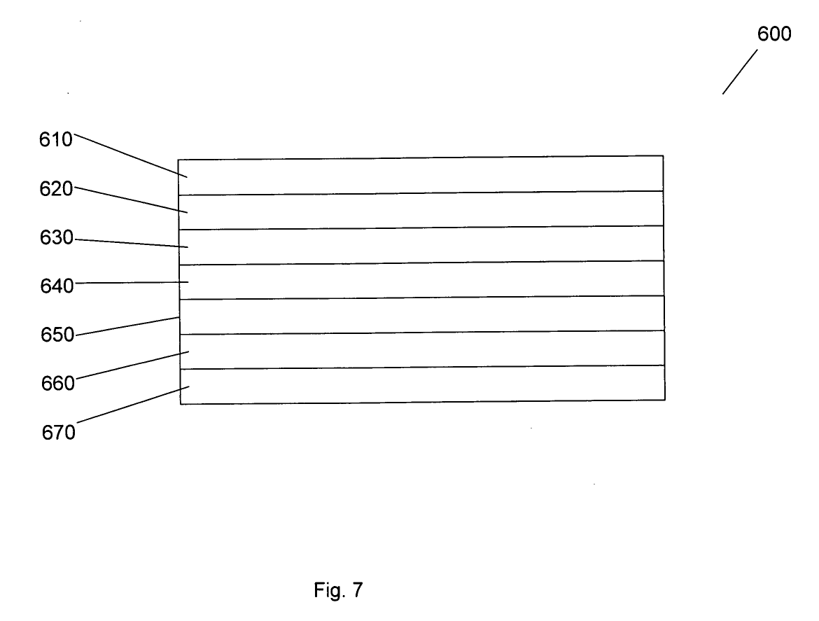

FIG. 7 shows a polymer photovoltaic cell 600 that includes substrates 610 and 670, electrically conductive layers 620 and 660, a hole blocking layer 630, a photoactive layer 640, and a hole carrier layer 650.

In general, substrate 610 and/or substrate 670 can be as described above with respect to the substrates in a DSSC. Exemplary materials include polyethylene tereplithalate (PET), polyethylene naphthalate (PEN), or a polyimide. An example of a polyimide is a KAPTON® polyimide film (available from E. I. du Pont de Nemours and Co.).

Generally, electrically conductive layer 620 and/or electrically conductive layer 670 can be as described with respect to the electrically conductive layers in a DSSC.

Hole blocking layer 630 is generally formed of a material that, at the thickness used in photovoltaic cell 600, transports electrons to electrically conductive layer 620 and substantially blocks the transport of holes to electrically conductive layer 620. Examples of materials from which layer 630 can be formed include LiF, metal oxides (e.g., zinc oxide, titanium oxide) and combinations thereof. While the thickness of layer 630 can generally be varied as desired, this thickness is typically at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick. In some embodiments, this distance is from 0.01 micron to about 0.5 micron. In some embodiments, layer 630 is a thin LiF layer. Such layers are disclosed, for example, in co-pending and commonly owned U.S. Ser. No. 10/258,708 [Q-04], which is hereby incorporated by reference.

Hole carrier layer 650 is generally formed of a material that, at the thickness used in photovoltaic cell 600, transports holes to electrically conductive layer 660 and substantially blocks the transport of electrons to electrically conductive layer 660. Examples of materials from which layer 650 can be formed include polythiophenes (e.g., PEDOT), polyanilines, polyvinylcarbazoles, polyphenylenes, polyphenylvinylenes, polysilanes, polythienylenevinylenes, polyisothianaphthanenes and combinations thereof. While the thickness of layer 650 can generally be varied as desired, this thickness is typically at least 0.01 micron (e.g., at least about 0.05 micron, at least about 0.1 micron, at least about 0.2 micron, at least about 0.3 micron, at least about 0.5 micron) and/or at most about five microns (e.g., at most about three microns, at most about two microns, at most about one micron). In some embodiments, this distance is from 0.01 micron to about 0.5 micron.

Photoactive layer 640 generally includes an electron acceptor material and an electron donor material.

Examples of electron acceptor materials include formed of fullerenes, oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups). In some embodiments, the electron acceptor material is a substituted fullerene (e.g., PCBM). In some embodiments, the fullerenes can be derivatized. For example, a fullerene derivative can includes a fullerene (e.g., PCBG), a pendant group (e.g., a cyclic ether such as epoxy, oxetane, or furan) and a linking group that spaces the pendant group apart from the fullerene. The pendant group is generally sufficiently reactive that fullerene derivative may be reacted with another compound (e.g., another fullerene derivative) to prepare a reaction product. Photoactive layers including derivatized fullerenes are disclosed, for example, in co-pending and commonly owned U.S. Ser. No. 60/576,033 [KON-021], which is hereby incorporated by reference. Combinations of electron acceptor materials can be used.

Examples of electron donor materials include discotic liquid crystals, polythiophenes, polyphenylenes, polyphenylvinylenes, polysilanes, polythienylvinylenes, and polyisothianaphthalenes. In some embodiments, the electron donor material is poly(3-hexylthiophene). In certain embodiments, photoactive layer 640 can include a combination of electron donor materials.

In some embodiments, photoactive layer 640 includes an oriented electron donor material (e.g., a liquid crystal (LC) material), an electroactive polymeric binder carrier (e.g., a poly(3-hexylthiophene) (P3HT) material), and a plurality of nanocrystals (e.g., oriented nanorods including at least one of ZnO, WO₃, or TiO₂). The liquid crystal (LC) material can be, for example, a discotic nematic LC material, including a plurality of discotic mesogen units. Each unit can include a central group and a plurality of electroactive arms. The central group can include at least one aromatic ring (e.g., an anthracene group). Each electroactive arm can include a plurality of thiophene moieties and a plurality of alkyl moities. Within the photoactive layer, the units can align in layers and columns. Electroactive arms of units in adjacent columns can interdigitate with one another facilitating electron transfer between units. Also, the electroactive polymeric carrier can be distributed amongst the LC material to further facilitate electron transfer. The surface of each nanocrystal can include a plurality of electroactive surfactant groups to facilitate electron transfer from the LC material and polymeric carrier to the nanocrystals. Each surfactant group can include a plurality of thiophene groups. Each surfactant can be bound to the nanocrystal via, for example, a phosphonic end-group. Each surfactant group also can include a plurality of alkyl moieties to enhance solubility of the nanocrystals in the photoactive layer. Examples of photovoltaic cells are disclosed, for example, in co-pending and commonly owned U.S. Ser. No. 60/664,298, filed Mar. 22, 2005 [KON-024], which is hereby incorporated by reference.

In certain embodiments, the electron donor and electron acceptor materials in layer 640 can be selected so that the electron donor material, the electron acceptor material and their mixed phases have an average largest grain size of less than 500 nanometers in at least some sections of layer 640. In such embodiments, preparation of layer 640 can include using a dispersion agent (e.g., chlorobenzene) as a solvent for both the electron donor and the electron acceptor. Such photoactive layers are disclosed, for example, in co-pending and commonly owned U.S. Ser. No. 10/258,713 [Q-03], which is hereby incorporated by reference.

Generally, photoactive layer 640 is sufficiently thick to be relatively efficient at absorbing photons impinging thereon to form corresponding electrons and holes, and sufficiently thin to be relatively efficient at transporting the holes and electrons to the electrically conductive layers of the device. In certain embodiments, layer 640 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, layer 640 is from 0.1 micron to about 0.2 micron thick.

In some embodiments, the transparency of photoactive layer 640 can change as an electric field to which layer 640 is exposed changes. Such photovoltaic cells are disclosed, for example, in co-pending and commonly owned U.S. Ser. No. 10/486,116 [Q-01], which is hereby incorporated by reference.

In some embodiments, cell 600 can further include an additional layer (e.g., formed of a conjugated polymer, such as a doped poly(3-alkylthiophene)) between photoactive layer 640 and electrically conductive layer 620, and/or an additional layer (e.g., formed of a conjugated polymer) between photoactive layer 640 and electrically conductive layer 660. The additional layer(s) can have a band gap (e.g., achieved by appropriate doping) of 1.8 eV. Such photovoltaic cells are disclosed, for example, in U.S. Pat. No. 6,812,399 [Q-05], which is hereby incorporated by reference.

Optionally, cell 600 can further include a thin LiF layer between photoactive layer 640 and electrically conductive layer 660. Such layers are disclosed, for example, in co-pending and commonly owned U.S. Ser. No. 10/258,708 [Q-04], which is hereby incorporated by reference.

In some embodiments, cell 600 can be prepared as follows. Electrically conductive layer 620 is formed upon substrate 610 using conventional techniques. Electrically conductive layer 620 is configured to allow an electrical connection to be made with an external load. Layer 630 is formed upon electrically conductive layer 620 using, for example, a solution coating process, such as slot coating, spin coating or gravure coating. Photoactive layer 640 is formed upon layer 630 using, for example, a solution coating process. Layer 650 is formed on photoactive layer 640 using, for example, a solution coating process, such as slot coating, spin coating or gravure coating. Electrically conductive layer 620 is formed upon layer 650 using, for example, a vacuum coating process, such as evaporation or sputtering.

In certain embodiments, preparation of cell 600 can include a heat treatment above the glass transition temperature of the electron donor material for a predetermined treatment time. To increase efficiency, the heat treatment of the photovoltaic cell can be carried out for at least a portion of the treatment time under the influence of an electric field induced by a field voltage applied to the electrically conductive layers of the photovoltaic cell and exceeding the no-load voltage thereof. Such methods are disclosed, for example, in co-pending and commonly owned U.S. Ser. No. 10/509,935 [Q-02], which is hereby incorporated by reference.

In general, a module containing multiple polymer photovoltaic cells can be arranged as described above with respect to DSSC modules containing multiple DSSCs.

Generally, polymer photovoltaic cells can be arranged with the architectures described above with respect to the architectures of DSSCs.

While certain embodiments of photovoltaic cells have been described, other embodiments are also known.

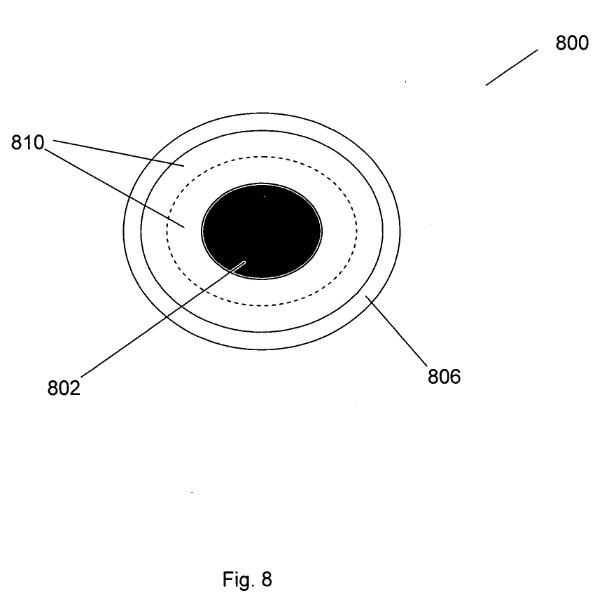

As an example, a photovoltaic cell can be in the shape of a fiber (e.g., a flexible fabric or textile). Examples of such photovoltaic cells are described, for example, in co-pending and commonly owned U.S. Ser. No. 10/351,607 [KON-002], which is hereby incorporated by reference. FIG. 8 depicts an illustrative embodiment of photovoltaic fiber 800 that includes an electrically conductive fiber core 802, a significantly light transmitting electrical conductor 806, and a photoconversion material 810, which is disposed between the electrically conductive fiber core 802 and the significantly light transmitting electrical conductor 806.

The electrically conductive fiber core 802 may take many forms. In the embodiment illustrated in FIG. 8, the electrically conductive fiber core 802 is substantially solid. In other embodiments, electrically conductive fiber core 802 may be substantially hollow. The photoconversion material 810 may include a photosensitized nanomatrix material and a charge carrier material. The charge carrier material may form a layer, be interspersed with the photosensitized nanomatrix material, or be a combination of both. The photosensitized nanomatrix material is adjacent to the electrically conductive fiber core. The charge carrier material is adjacent to the electrically conductive fiber core.

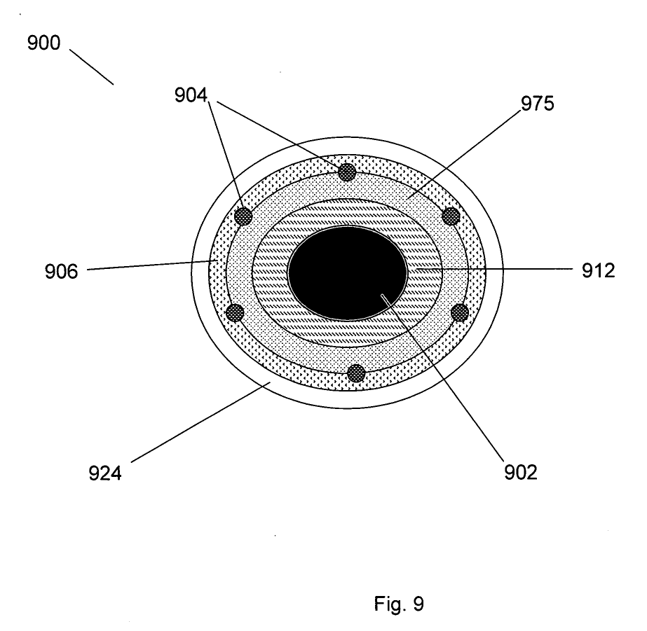

FIG. 9 depicts a photovoltaic material 900 that includes a fiber 902, one or more wires 904 that are imbedded in a significantly light transmitting electrical conductor 906, a photosensitized nanomatrix material 912, a charge carrier material 915, and a protective layer 924. The wires 904 may also be partially imbedded in the charge carrier material 915 to, for example, facilitate electrical connection of the photovoltaic material 900 to an external load, to reinforce the significantly light transmitting electrical conductor 906, and/or to sustain the flexibility of the photovoltaic material 900. Preferably, the wire 904 is an electrical conductor and, in particular, a metal electrical conductor. Suitable wire 904 materials include, but are not limited to, copper, silver, gold, platinum, nickel, palladium, iron, and alloys thereof. In one illustrative embodiment, the wire 904 is between about 0.5 μm and about 100 μm thick. In another illustrative embodiment, the wire 904 is between about 1 μm and about 10 μm thick.

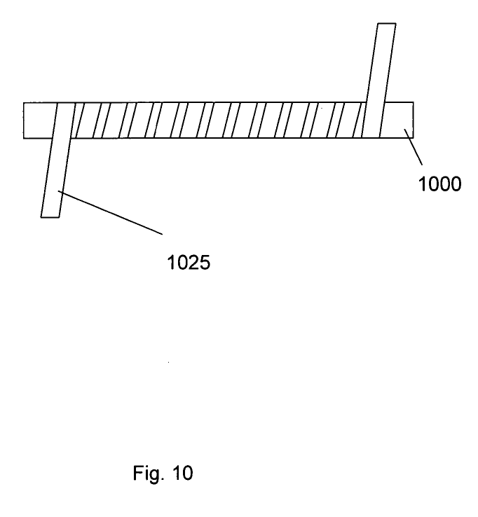

FIG. 10 shows a method of forming a photovoltaic material 1000 that has an electrically conductive fiber core, a significantly light transmitting electrical conductor, and a photoconversion material, which is disposed between the electrically conductive fiber core and the significantly light transmitting electrical conductor. According to the method, the outer surface of the conductive fiber core is coated with titanium dioxide nanoparticles. The nanoparticles are then interconnected by, for example, sintering, or preferably by contacting the nanoparticles with a reactive polymeric linking agent such as, for example, poly(n-butyl titanate), which is described in more detail below. The interconnected titanium dioxide nanoparticles are then contacted with a photosensitizing agent, such as, for example, a 3×10-4 M N3-dye solution for 1 hour, to form a photosensitized nanomatrix material. A charge carrier material that includes a gelled electrolyte is then coated on the photosensitized nanomatrix material to complete the photoconversion material. A strip 625 of transparent polymer from about 2.5 μm to about 6 μm thick, coated with a layer of ITO that in turn has been platinized, is wrapped in a helical pattern about the photovoltaic material 1000 with the platinized side of the strip 1025 in contact with the charge carrier material. In this illustrative embodiment, the strip 1025 of transparent polymer is the significantly light transmitting electrical conductor. In other illustrative embodiments, the significantly light transmitting electrical conductor is formed using the materials described in connection with this application and the applications that are incorporated by reference.

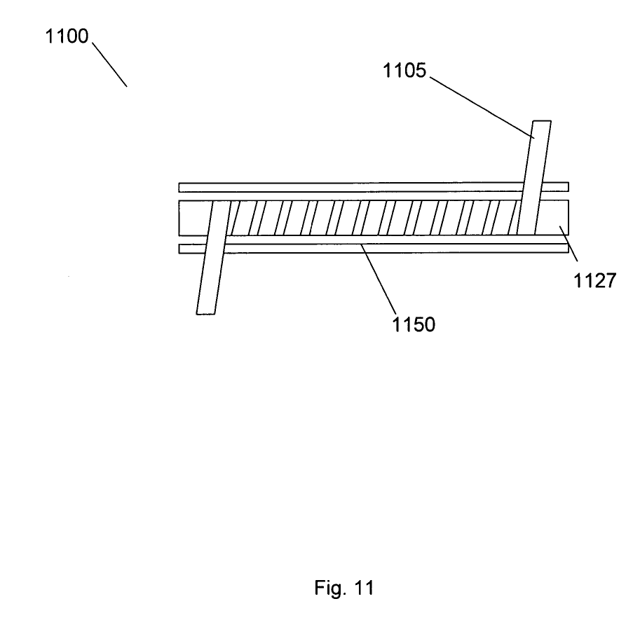

Referring to FIG. 11, in another illustrative embodiment, a photovoltaic material 1100 is formed by wrapping a platinum or platinized wire 1105 around a core 1127 including a photoconversion material disposed on either an electrically conductive fiber core or on an inner electrical conductor in turn disposed on an insulative fiber. A strip 1150 of transparent polymer coated with a layer of ITO, which has been platinized, is wrapped in a helical pattern about the core 1127 with the platinized side of the strip 1150 in contact with the wire 1105 and the charge carrier material of the core 1127.

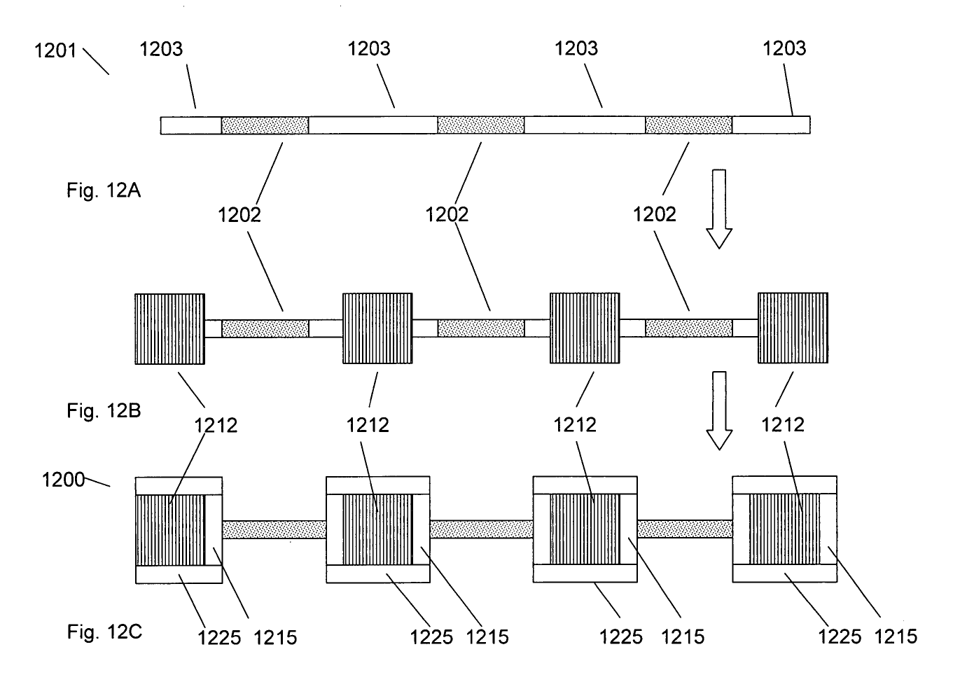

FIGS. 12A, 12B, and 12C depict other illustrative embodiments of a photovoltaic material 1200, constructed in accordance with the invention. The photovoltaic material 1200 includes a metal-textile fiber 1201, which has metallic electrically conductive portions 1202 and textile portions 1203. The textile portions 1203 may be electrically conductive or may be insulative and coated with an electrical conductor. Referring to FIG. 12B, a dispersion of titanium dioxide nanoparticles is coated on the outer surface of portions of the textile portions 1203 of the metal-textile fiber 1201. The particles are then interconnected preferably by contacting the nanoparticles with a reactive polymeric linking agent such as poly(n-butyl titanate), which is further described below. The interconnected titanium dioxide nanoparticles are then contacted with a photosensitizing agent, such as a N3 dye solution, for 1 hour to form a photosensitized nanomatrix material 1212.

Referring to FIG. 12C, a charge carrier material 1215 including a solid electrolyte is then coated on the textile portions 1203. A strip 1225 of PET coated with ITO, that in turn has been platinized, is disposed on the photosensitized nanomatrix material 1212 and the charge carrier material 1215. The platinized ITO is in contact with the charge carrier material 1215.

As indicated, the photovoltaic fibers may be utilized to form a photovoltaic fabric. The resultant photovoltaic fabric may be a flexible, semi-rigid, or rigid fabric. The rigidity of the photovoltaic fabric may be selected, for example, by varying the tightness of the weave, the thickness of the strands of the photovoltaic materials used, and/or the rigidity of the photovoltaic materials used. The photovoltaic materials may be, for example, woven with or without other materials to form the photovoltaic fabric. In addition, strands of the photovoltaic material, constructed according to the invention, may be welded together to form a fabric.

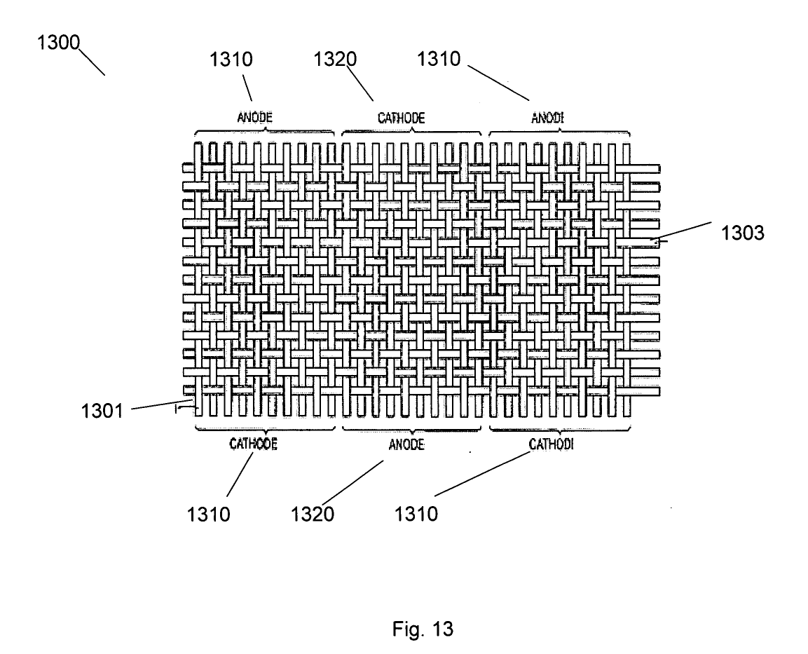

FIG. 13 depicts one illustrative embodiment of a photovoltaic fabric 1300 that includes photovoltaic fibers 1301, according to the invention. As illustrated, the photovoltaic fabric 1300 also includes non-photovoltaic fibers 1303. In various illustrative embodiments, the non-photovoltaic fibers 1303 may be replaced with photovoltaic fibers. FIG. 13 also illustrates anodes 1310 and cathodes 1320 that are formed on the photovoltaic fabric 1300 and that may be connected to an external load to form an electrical circuit. The anodes 1310 may be formed by a conductive fiber core or an electrical conductor on an insulative fiber, and the cathodes 1320 may be formed by significantly light transmitting electrical conductors. In FIG. 13, each edge of the photovoltaic fabric 1300 is constructed in an alternating fashion with the anodes 1310 and cathodes 1320 formed from photovoltaic fibers 1301. In another illustrative embodiment, each edge of photovoltaic fabric 1300 is constructed from just one anode or just one cathode, both of which are formed from either photovoltaic fibers, non-photovoltaic fibers, or a combination of both.

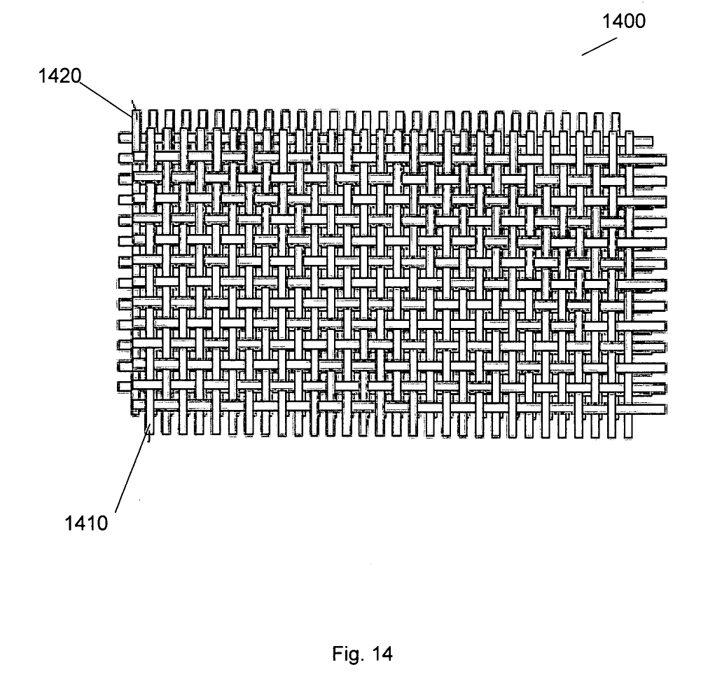

FIG. 14 shows a photovoltaic fabric 1400 formed by a two-component photovoltaic material. According to the illustrative embodiment, each component is formed by a mesh, where one mesh serves as the anode 1410 and the other as the cathode 1420. Each mesh (or component) is connected to a different busbar, which in turn may be connected to opposite terminals of an external load. Hence, a single large-area, fabric-like photovoltaic cell is produced.

According to the illustrated embodiment, the mesh material may be any material suitable as a fiber material. For example, the mesh material may include electrically conductive fiber cores, electrically insulative fiber cores coated with an electrical conductor, or a combination of both. In one embodiment, the anode mesh is made of a metal fiber with a redox potential approximately equal to that of ITO. In another embodiment, the mesh is composed of a plastic fiber, e.g., nylon that is metalized by, for example, vacuum deposition or electroless deposition.

In one illustrative embodiment, the anode 1410 mesh of the photovoltaic fabric 1400 is formed by coating the mesh with a dispersion of titanium dioxide nanoparticles by, for example, dipping or slot coating in a suspension. The titanium dioxide nanoparticles are interconnected, for example, by a sintering, or preferably by a reactive polymeric linking agent, such as poly(n-butyl titanate) described in more detail below. After coating with the titania suspension, but prior to either sintering or crosslinking, an air curtain can be used to remove excess titania from the spaces between the fibers of the mesh. Likewise, this, or some other functionally equivalent method, may be used to clear these spaces of excess material after each of the subsequent steps in the preparation of the final photovoltaic fabric. Subsequently, the mesh is slot coated or dipped in a photosensitizing agent solution, such as N3 dye, followed by washing and drying. A charge carrier including a solid electrolyte (e.g., a thermally-reversible polyelectrolyte) is applied to the mesh to from the anode 1410 mesh. In another illustrative embodiment, the cathode 1420 mesh of the photovoltaic fabric 1400 is formed as a platinum-coated mesh, such as, for example, a platinum-coated conductive fiber core mesh or a platinum-coated plastic mesh.

To form the photovoltaic fabric 1400, the anode 1410 mesh and cathode 1420 mesh are brought into electrical contact and aligned one over the other, so that the strands of each mesh are substantially parallel to one another. Perfect alignment is not critical. In fact, it may be advantageous from the standpoint of photon harvesting to slightly misalign the two meshes. The photovoltaic fabric 1400 may be coated with a solution of a polymer that serves as a protective, transparent, flexible layer.

One of the advantages of the photovoltaic fabric 1400 is its relative ease of construction and the ease with which the anode 1410 and cathode 1420 may be connected to an external circuit. For example, the edges of each mesh, one edge, multiple edges, or all edges may be left uncoated when the coating operations described above are performed. The anode 1410 and cathode 1420 are each electrically connected to its own metal busbar. An advantage of this illustrative embodiment is the elimination of the possibility that severing one wire would disable the entire photovoltaic fabric.

As another example, a photovoltaic cell may further include one or more spacing elements disposed between the electrically conductive layers. Examples of spacing elements include spheres, mesh(es) and porous membrane(s). In certain embodiments, the spacing element(s) can maintain a distance (e.g., a substantially constant and/or substantially uniform distance) between electrically conductive layers of different charge (e.g., during operation and/or bending of a photovoltaic cell). This can, for example, reduce the likelihood that the electrically conductive layer and photoactive material will contact each other. Photovoltaic cells having one or more spacing elements are disclosed, for example, in co-pending and commonly owned U.S. Ser. No. 11/033,217, filed Jan. 10, 2005 [KON-019], which is hereby incorporated by reference.

As an additional example, in certain embodiments, a photovoltaic cell can have an absorption maximum that is at relatively long wavelength region and/or relatively high layer efficiency. Such cells are disclosed, for example, in published international application WO04/025746 [SA-5], which is hereby incorporated by reference.

As a further example, in some embodiments, the photoactive layer can include at least one mixture of two different fractions of a functional polymer (e.g., contained in a solvent). Such photovoltaic cells are disclosed, for example, in co-pending and commonly owned U.S. Ser. No. 10/515,159 [SA-7], which is hereby incorporated by reference.

As an additional example, in certain embodiments, a photovoltaic cell can be a tandem cell in which two or more photoactive layers are arranged in tandem. Such cells can include of an optical and electrical series connection of two photoactive layers. The cells can have at least one shared electrically conductive layer (e.g., placed between two photovoltaically active layers). Such photovoltaic cells are disclosed, for example, in published international application WO 2003/107453 [SA-8], which is hereby incorporated by reference.

As another example, in some embodiments, a photovoltaic cell can optionally include an additional layer having an asymmetric conductivity is placed between at least one of the electrically conductive layers and the photoactive layer. Such photovoltaic cells are disclosed, for example, in published international application WO 2004/112162 [SA-9], which is hereby incorporated by reference.

As an additional example, in some embodiments, the electrically conductive layers can be formed of spherical allotropes (e.g., silicon and/or carbon nanotubes). The electrically conductive layers can either exclusively contain allotropes and/or contain allotropes that are embedded in an organic functional polymer. Such photovoltaic cells are disclosed, for example, in published international application WO03/107451 [SA-15], which is hereby incorporated by reference.

As another example, in certain embodiments, one or more layers of a photovoltaic cell can be structured. Such photovoltaic cells are disclosed, for example, in published international application WO04/025747 [SA-16], which is hereby incorporated by reference.

As a further example, in some embodiments, a photovoltaic cell can include an improved top electrically conductive layer and to a production method therefor. The top electrically conductive layer is made of an organic material that is applied, for example, by using printing techniques. Such photovoltaic cells are disclosed, for example, in published international application WO2004/051,756 [SA-17], which is hereby incorporated by reference.

Moreover, the photovoltaic devices and modules including the photovoltaic devices can generally be used as a component in any intended system. Examples of such systems include roofing, package labeling, battery chargers, sensors, window shades and blinds, awnings, opaque or semitransparent windows, and exterior wall panels. As an example, one or more photovoltaic cells are incorporated into eyeglasses (e.g., sunglasses). Such sunglasses are disclosed, for example, in co-pending and commonly owned U.S. Ser. No. 10/504,091 [SA-2], which is hereby incorporated by reference. As another example, one or more photovoltaic cells are incorporated into a thin film energy system. The thin film energy system can include one or more thin film energy converters that each include one or more photovoltaic cells. Such systems are disclosed, for example, in co-pending and commonly owned U.S. Ser. No. 10/498,484 [SA-3], which is hereby incorporated by reference. As an additional example, a photovoltaic cell can be used in a flexible display (e.g., the photovoltaic cell can serve as a power source for the flexible display). Examples of such flexible displays are disclosed, for example, in co-pending and commonly owned U.S. Ser. No. 10/350,812 [KON-005], which is hereby incorporated by reference. As a further example, one or more photovoltaic cells are integrated into a chip card. Such chip cards are disclosed, for example, in co-pending and commonly owned WO 2004/017256, PCT/DE2003/002463 [SA-4], which is hereby incorporated by reference. As another example, a photovoltaic cell can be used to power a multimedia greeting card or smart card. Such photovoltaic cells and systems are disclosed, for example, in U.S. Ser. No. 10/350,800 [KON-006], which is hereby incorporated by reference.

While DSSCs and polymer cells have been described, more generally any type of photovoltaic cells can include one or more of the features described above. As an example, in some embodiments, one or more hybrid photovoltaic cells can be used. In general, a hybrid photovoltaic cell has a photoactive layer that includes one or more semiconductors, such as a nanoparticle semiconductor; materials (e.g., one or more of the semiconductor materials described above); and one or more polymer materials that can act as an electron donor (e.g., one or more of the polymer materials described above).

An aspect of the present invention relates to combining photovoltaic facilities with communication facilities. While many of the photovoltaic/communication facility embodiments described herein describe particular photovoltaic facilities and or particular communication facilities, these embodiments are merely examples; the applicants of the present invention envision many equivalent systems and methods which are encompassed by the present invention. For example, a photovoltaic communication facility embodiment herein below may include a photovoltaic facility described herein above; however, such photovoltaic facility may also comprise a photovoltaic facility that is not described herein.

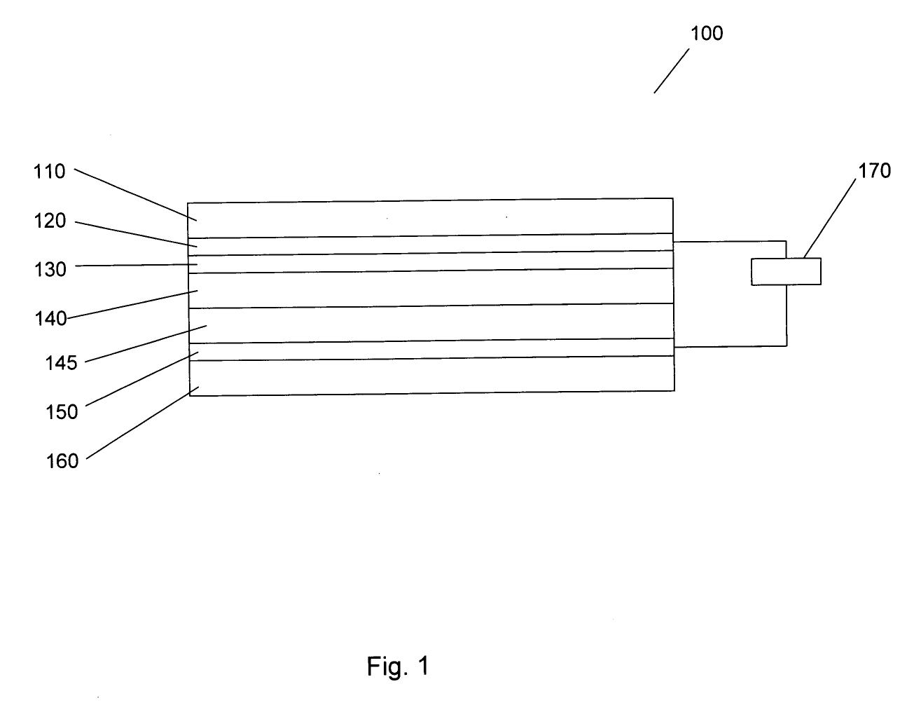

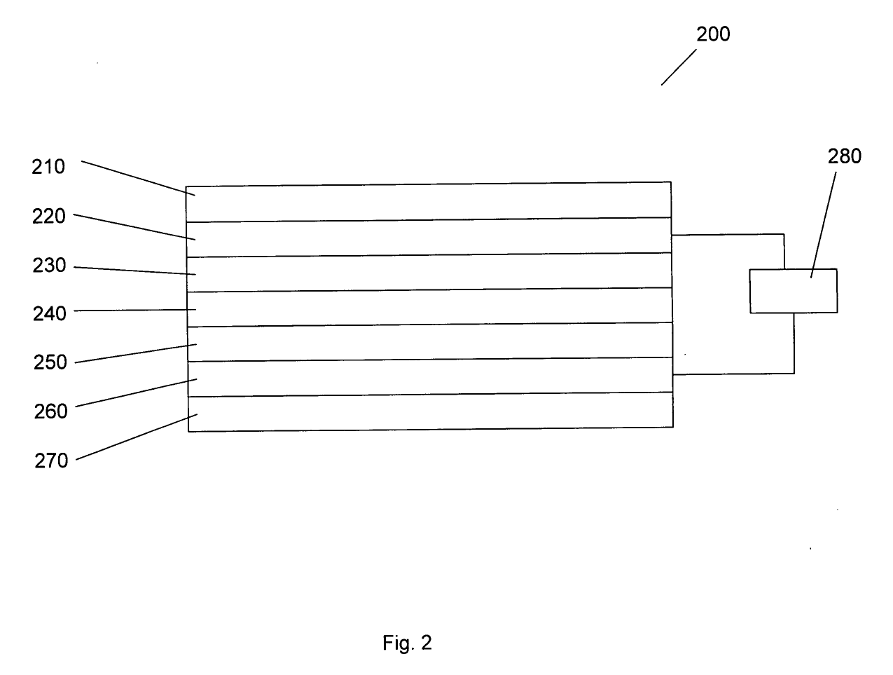

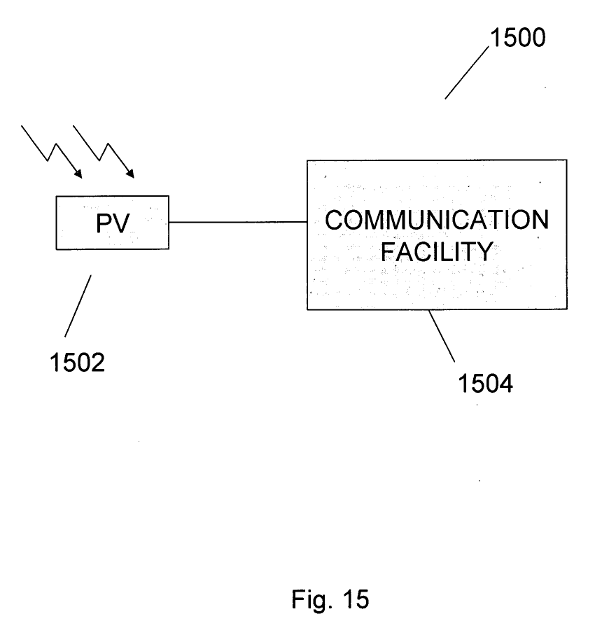

FIG. 15 illustrates a photovoltaic communication facility 1500 according to the principles of the present invention. In embodiments, the photovoltaic communication facility 1500 includes a photovoltaic facility 1502 and a communication facility 1504. In embodiments, the photovoltaic facility 1502 may be a photovoltaic facility described herein above, such as those described in connection with FIGS. 1-7, and it may be another type of photovoltaic facility adapted to generate electricity from light. In embodiments, the communication facility 1504 may be a facility adapted to communicate by mail, email, instant message, chat, internet relay channel, audio, video, television, telephone, animation, flash, text message, vibration, point-to-point methods, broadcast, cable, wireless means and wired means. In embodiments, the communication facility 1504 may be a facility adapted to communicate using natural language, computer language, foreign language, sign language, a network, a LAN, a WAN, an extranet, an ethernet, a satellite, a transmitter, a bridge rectifier, an antenna, a copper wire, fiber optics, polymer optics, coax cables, a megaphone, a microphone, a loud speaker, an amplifier, a walkie talkie, a personal digital assistant, a web appliance, a radio, ISDN, FDDI, CDMA, VoIP, shortware, DSL, SS7, ultra wide band, a mobile exchange server, acoustics, RF, microwaves, light, infrared, ultra violet, visible light, laser, radar, sonar, VHF, UHF, FM, AM, XM, a server, a computer, a computing device, power lines, packets, TCP/IP, IP, multiplexing, telegraph, WIFI, WIMAX, RSS, XML, 3G, TDMA and FFT. In embodiments, the communication facility 1504 may be a sign, light, traffic signal, windsock, rotary beacon, weather vane, ship buoy, runway signal or rail signal. Examples of certain communication facilities 1504 are included in the embodiments below for further illustrative purposes; however, these examples should not be construed as limiting; the applicants of the present invention envision many equivalents, and such equivalents are encompassed by the present invention. In embodiments, the photovoltaic facility 1502 is adapted to power and is associated with the communication facility 1504. For example, a communication facility may require power to perform a certain function, and the photovoltaic facility may be adapted to generate the requisite power and may be connected to the communication facility. In embodiments, the association between the photovoltaic facility 1502 and the communication facility 1504 may be continuous, intermittent, wired, wireless, or otherwise configured.

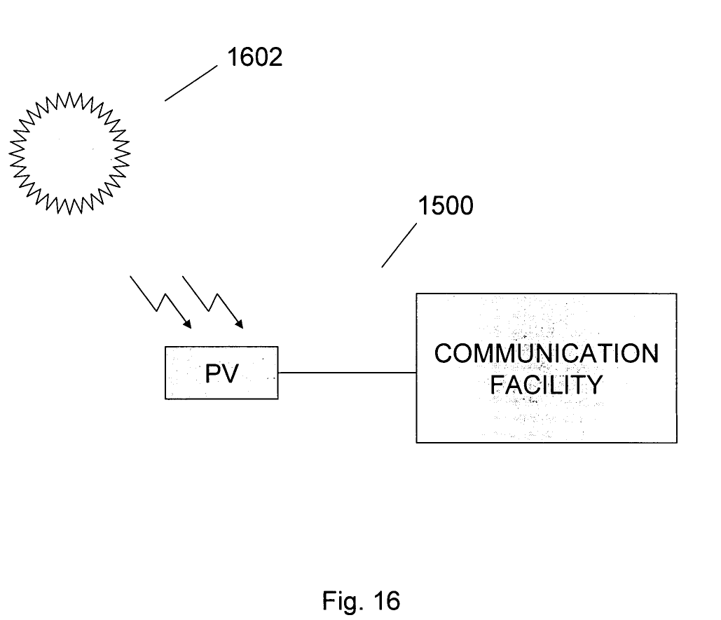

FIG. 16 illustrates a photovoltaic communication facility 1500 in the presence of sunlight 1602 according to the principles of the present invention. In embodiments, the photovoltaic communication facility 1500 may obtain its power from the sun. In embodiments, the sunlight may be reflected sunlight, refracted sunlight, direct sunlight, or otherwise directed to the photovoltaic facility 1500. In embodiments, the light may be a phenomenon that occurs at the nearinfrared, infrared, near UV, UV, or other non-visible radiation.

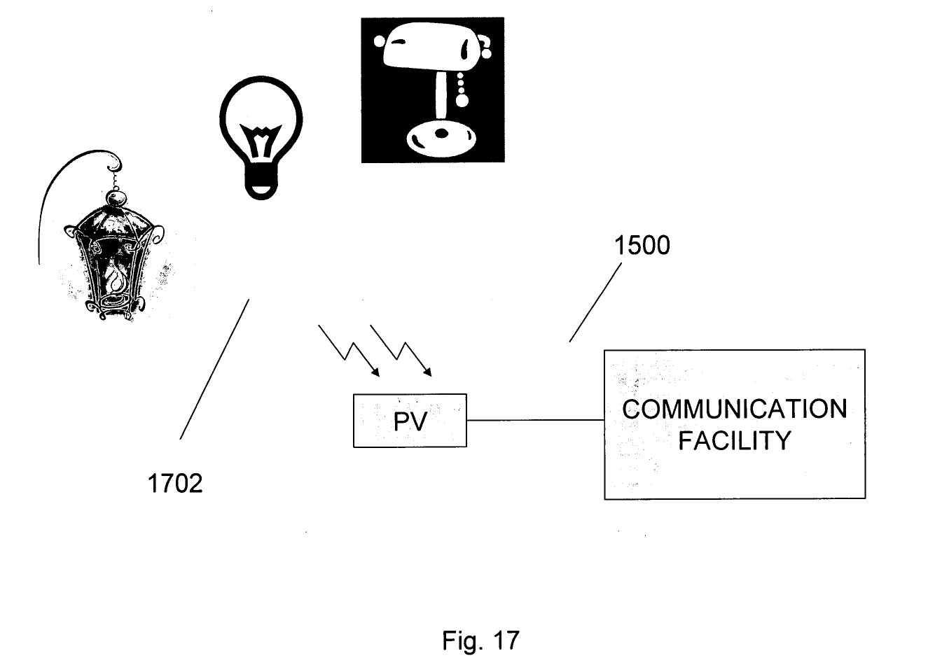

FIG. 17 illustrates a photovoltaic communication facility 1500 in the presence of artificial light 1702 according to the principles of the present invention. In embodiments, the photovoltaic communication facility 1500 may obtain its power from an artificial light source, such as a light, lighting fixture, incandescent light, halogen light, fluorescent light, HID light, LED light, display, OLED light, plasma light, plasma display, LCD, LCD display, computer display, PDA display, mobile phone display, or other facility that generates light.

In embodiments, the photovoltaic may be tuned to a specific wavelength, frequency, bandwidth, and other light spectrum or radiation. For example, a uniform, undergarment, blanket, jacket, or other fabric or facility may be tuned to a particular light source. In embodiments, the tuned spectrum may be used to activate and or power the photovoltaic system. For example, a tuned photovoltaic panel may be mated to specific light, and, when the compatible light is present, the sensor may respond because it understands that the light belongs to this panel. In embodiments, the light is an addressing facility for addressing this photovoltaic by tuning between the light source and the photovoltaic. In embodiments, the tuning is a type of communication protocol. For example, to communicate to it wirelessly one transmits at this wavelength. In embodiments, the addressing scheme is used for security. For example, it may be used to generate a card key. If the user has a photovoltaic light pulse that is read by the photovoltaic facility, then a light activated lock may open.

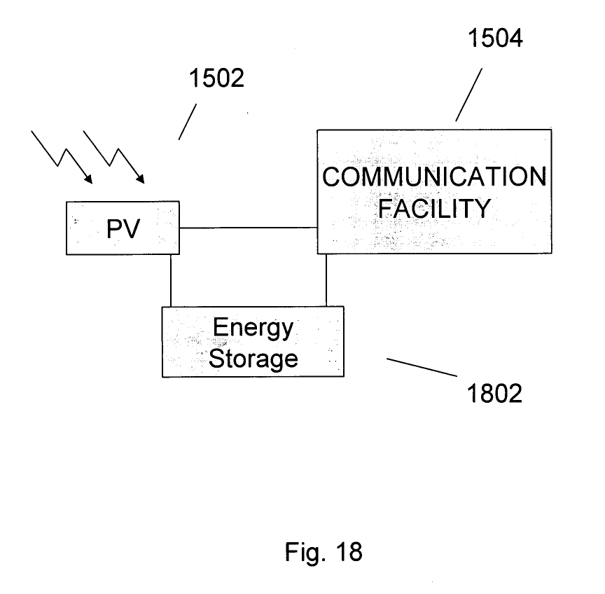

FIG. 18 illustrates a photovoltaic communication facility including a photovoltaic facility 1502, a communication facility 1504, and an energy storage facility 1802 according to the principles of the present invention. In embodiments, the energy storage facility 1802 stores energy for the photovoltaic communication facility. In embodiments, the energy storage facility 1802 is adapted to be connected to the photovoltaic facility 1502 and or the communication facility. In embodiments, the connection may be continuous, intermittent, wired, wireless, or otherwise configured. In embodiments the energy storage facility 1802 may be adapted in parallel, series or other connection topology. In embodiments, the storage facility 1802 stores energy generated by the photovoltaic facility 1502 or delivers energy to the communication facility 1504, or it may both store and deliver energy. For example, the energy storage facility may be and/or include a battery, chargeable cell, rechargeable cell, energy retention cell, capacitor, capacitance facility, inductor, inductance facility, hydrogen storage facility, split water facility, electrochemical storage facility, potential energy storage facility, mechanical energy storage (e.g. spring), or other facility adapted to store energy. In embodiments, the energy storage facility 1802 may be a super capacitor. For example, a super capacitor may generate high peak energies, but the photovoltaic facility may operate at a lower level.

In embodiments a vending machine is associated with a photovoltaic facility as described herein. For example, it may be a self-powered vending machine; it may have a lower power requirement; and/or the power requirement may come in discrete bursts. In embodiments, the photovoltaic facility may be associated with advertising. For example, such a system may be used to know what is on a shelf. In embodiments, the photovoltaic facility may be associated with traceability of a product. For example, the system may be employed with an RFID system, or other ID system, including a transmitting ID system, associated with a product to trace the product through its life cycle, including through manufacturing, distribution, use, and disposal. In embodiments, such a photovoltaic ID system may be linked to point of purchase. In embodiments, an ID facility (e.g. RFID, ID transmission, keyed ID transmission, data enabled ID transmission) may be combined with a communication facility and or a photovoltaic facility.

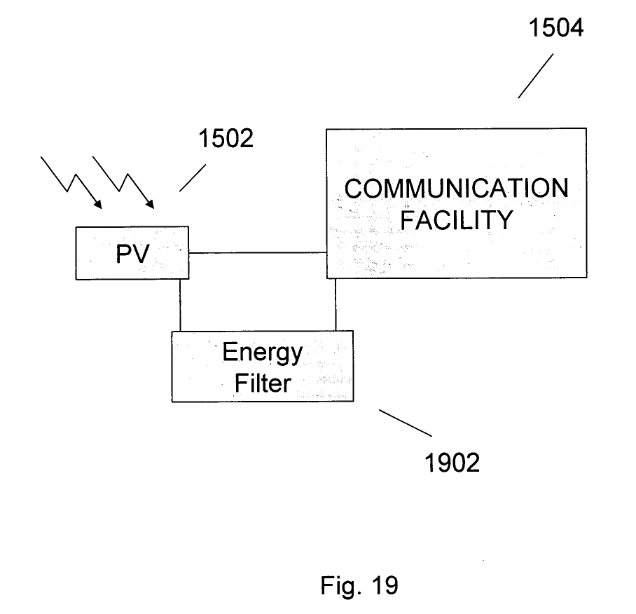

FIG. 19 illustrates a photovoltaic communication facility including a photovoltaic facility 1502, a communication facility 1504, and an energy filtering facility 1902 according to the principles of the present invention. In embodiments, the energy filtering facility 1902 filters energy, voltage, current, power, or other energy for the photovoltaic communication facility. In embodiments, the energy filtering facility 1902 is adapted to be connected to the photovoltaic facility 1502 and or the communication facility. In embodiments, the connection may be continuous, intermittent, wired, wireless, or otherwise configured. In embodiments, the energy filtering facility 1902 may be adapted in parallel, series, or other connection topology. In embodiments, the energy filtering facility 1902 filters energy generated by the photovoltaic facility 1502 and/or delivers filtered energy to the communication facility 1504. For example, the energy filtering facility 1902 may be and/or include a capacitor, capacitance facility, inductor, inductance facility, processor adapted to filter, circuit adapted to filter, transformer circuit, or other facility adapted to filter energy. In embodiments, the energy filtering facility 1902 is adapted to remove noise from the power. For example, when the photovoltaic system is powered by light, it is difficult to predict the incoming power quality; the energy filtering facility 1902 may be adapted to remove noise from the power. In embodiments, algorithms may be employed (e.g. through a processor described below) to predict and or manipulate the power output for battery charging or power applications. In embodiments, the algorithms may use simulations based on the type of photovoltaic facility material to improve the predictions and regulations.

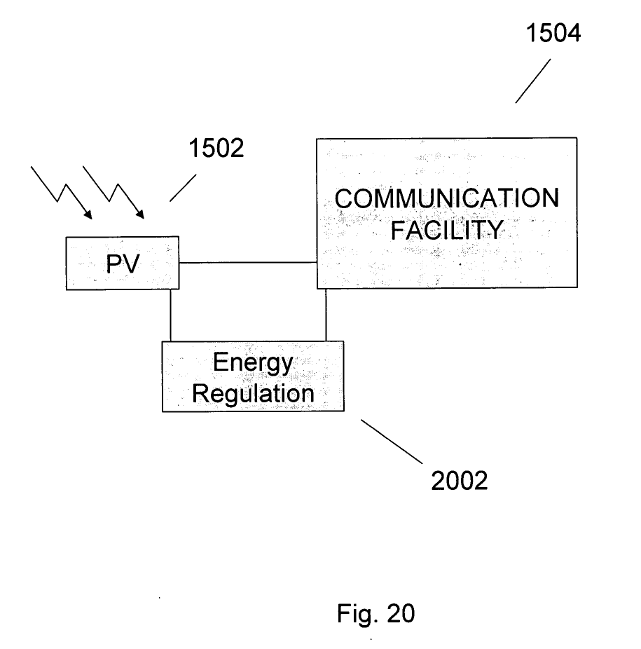

FIG. 20 illustrates a photovoltaic communication facility including a photovoltaic facility 1502, a communication facility 1504, and an energy regulation facility 2002 according to the principles of the present invention. In embodiments, the energy regulation facility 2002 regulates energy, voltage, current, power, or other energy for the photovoltaic communication facility. In embodiments, the energy regulation facility 2002 is adapted to be connected to the photovoltaic facility 1502 and/or the communication facility. In embodiments, the connection may be continuous, intermittent, wired, wireless, or otherwise configured. In embodiments, the energy regulation facility 2002 may be adapted in parallel, series, or other connection topology. In embodiments, the energy regulation facility 2002 regulates energy generated by the photovoltaic facility 1502 and/or delivers regulated energy to the communication facility 1504. For example, the energy regulation facility 2002 may be and/or include a capacitor, capacitance facility, inductor, inductance facility, processor adapted to regulate, circuit adapted to regulate, transformer circuit, or other facility adapted to filter energy.

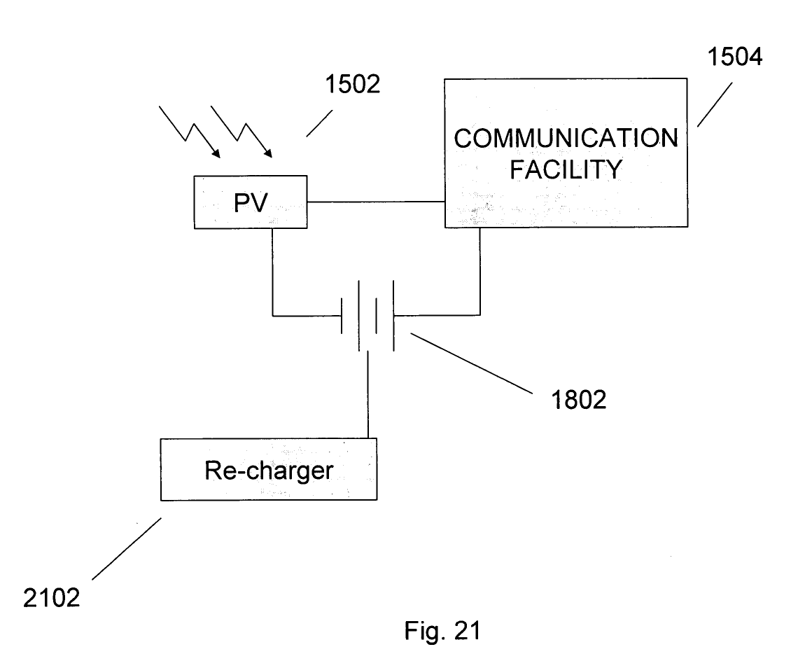

FIG. 21 illustrates a photovoltaic communication facility including a photovoltaic facility 1502, a communication facility 1504, an energy storage facility 1802, and a recharging facility 2102 according to the principles of the present invention. In embodiments, the recharging facility 2102 is adapted to recharge energy, voltage, current, power, or other energy associated with the photovoltaic communication facility. In embodiments, the recharging facility 2102 is adapted to be connected to the photovoltaic facility 1502, the energy storage facility 1802, and/or the communication facility 1504. In embodiments, the connections may be continuous, intermittent, wired, wireless, or otherwise configured. In embodiments, the recharging facility 2102 may be adapted in parallel, series, or other connection topology. In embodiments, the recharging facility 2102 recharges energy stored by the energy storage facility. For example, the recharging facility 2102 may be and/or include a capacitive recharger, inductive recharger, mechanical recharger, electrical recharger, motion recharger, sensor recharger, or other recharging facility. In embodiments, the recharging facility may be adapted to receive power from AC sources, DC sources, photovoltaic sources, RF sources, inductively coupled sources, capacitively coupled sources, or other power sources. In embodiments, the recharging facility is adapted to receive power from multiple sources.

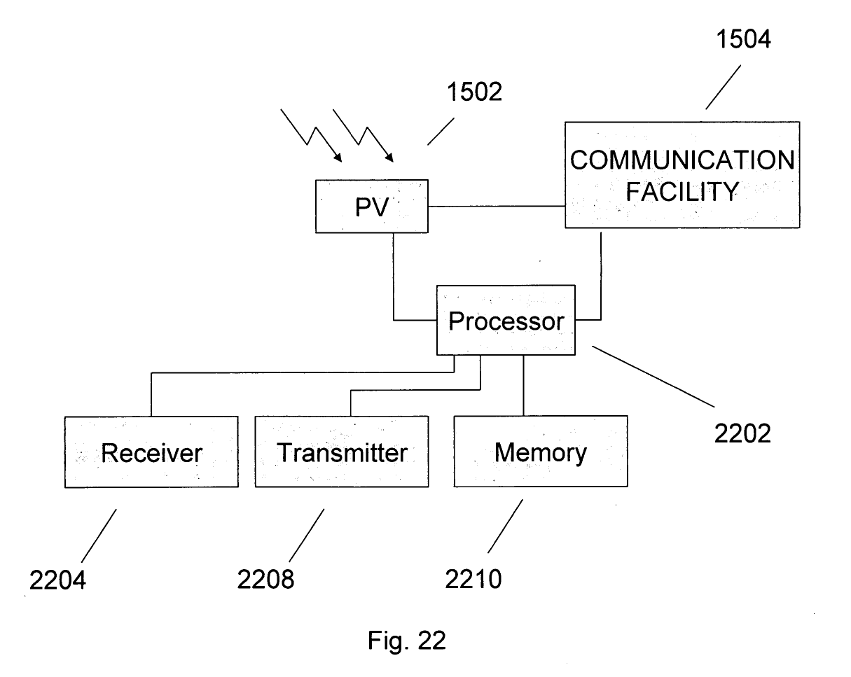

FIG. 22 illustrates a photovoltaic communication facility including a photovoltaic facility 1502, a communication facility 1504, a processing facility 2202, a receiving facility 2204, a transmitting facility 2208, and a memory facility 2210 according to the principles of the present invention. In embodiments, the processing facility 2202 may process signals received from external sources and/or process signals from the communication and/or photovoltaic facilities. In embodiments, the processing facility 2202 may be associated with a transmitting facility 2208 adapted to transmit data, information, signals, and the like. In embodiments, the processing facility may be associated with a receiving facility 2204 adapted to receive data, information, signals, and the like. In embodiments, the processing facility 2202 may be associated with a memory facility 2210 adapted to store data, information, signals, and the like. In embodiments, the connections among the several facilities may be continuous, intermittent, wired, wireless, or otherwise configured. In embodiments, the facilities may be connected in parallel, series, or other connection topology. In embodiments, the processor may be a microprocessor, a circuit, a passive circuit, an active circuit, or other facility adapted for processing data, signals, information and the like. For example, the receiver may be adapted to receive an initiation signal to initiate a communication facility function in a wireless or wired fashion. Once the signal is received by the receiving facility, the receiving facility may communicate information, data, a signal, or the like to the processor, and the processor may initiate a communication function. In embodiments, the transmitter is adapted to transmit as directed by the processor. For example, the processor may collect data from the communication facility and transmit the data, or indication from the data, through the transmitter in a wireless or wired fashion. In embodiments, the processor stores data, information, signals, and/or the like in the memory facility 2210. For example, the processor may store data associated with a signal received by the receiving facility, data associated with a signal transmitted by the transmitting facility, and/or data gathered from the photovoltaic facility and/or the communication facility. For example, the communication facility may produce data, and the processor may store the data in memory. By way of another example, data may be received that relate to the system, and the processor may save information relating to the received information. The received information may be calibration information, initiation information, termination information, collection information, or other information.

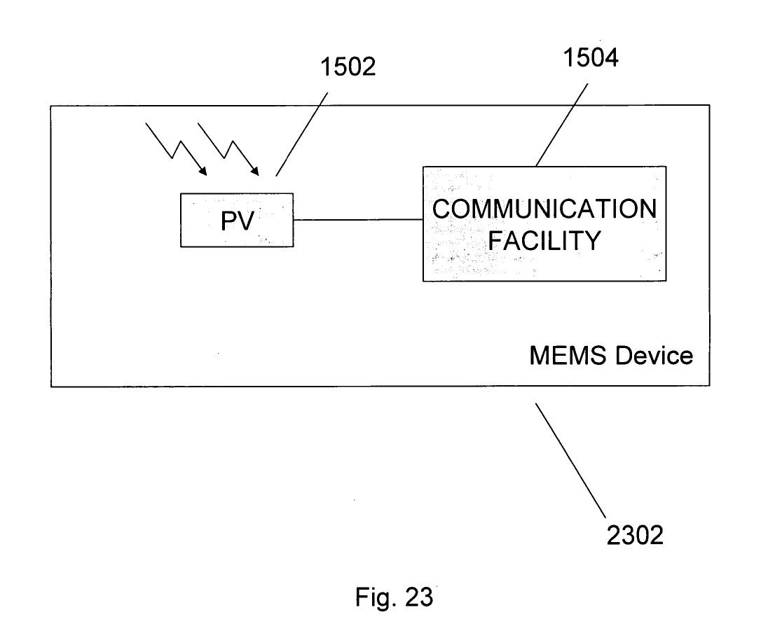

FIG. 23 illustrates a photovoltaic communication facility including a photovoltaic facility 1502, a communication facility 1504, and an MEMS facility 2302 according to the principles of the present invention. In embodiments, the photovoltaic communication facility may be incorporated with, incorporated onto, and/or associated with an MEMS facility 2302.

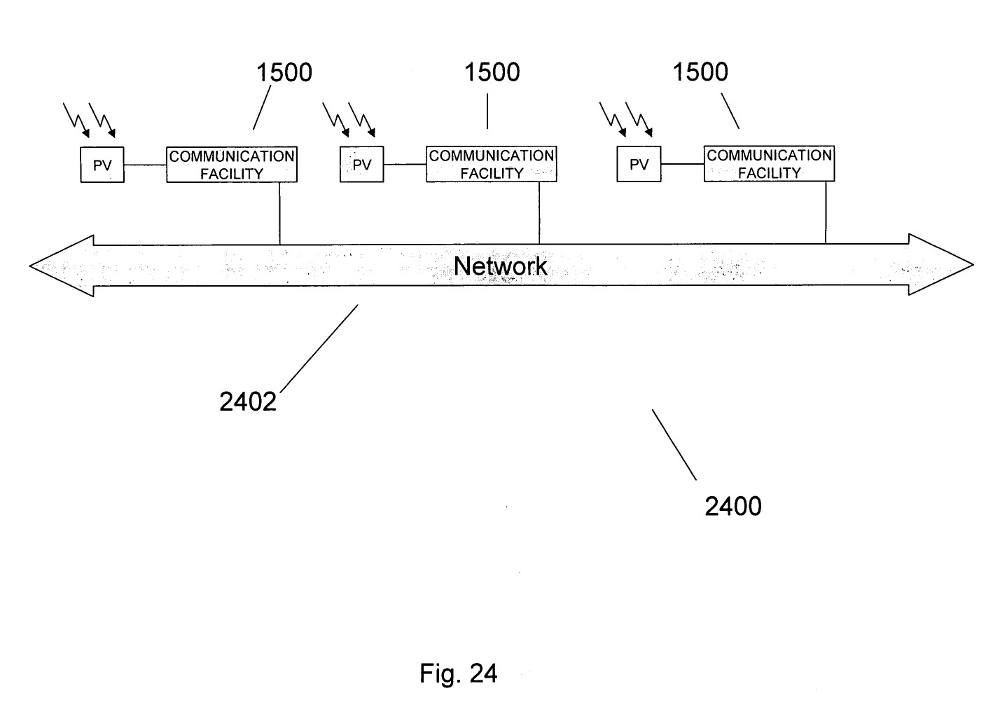

FIG. 24 illustrates a photovoltaic communication facility network 2400 according to the principles of the present invention. In embodiments, a photovoltaic communication facility(ies) 1500 or a photovoltaic communication facility associated with other facilities (e.g. those facilities described in connection with FIGS. 15-23) may be associated with a network 2402. For example, a plurality of photovoltaic communication facilities may be adapted to be connected to a network. The photovoltaic communication facilities for example may include transmitters and/or addressable controllers. The network may be a local area network, personal area network, wide area network, the Internet, or other network facility. For example, a network of communication facilities may be used to interface with other networks and photovoltaic or other devices. In embodiments, the photovoltaic communication facilities may include wireless communication facilities such as Bluetooth, ZigBee, or other personal area technologies.

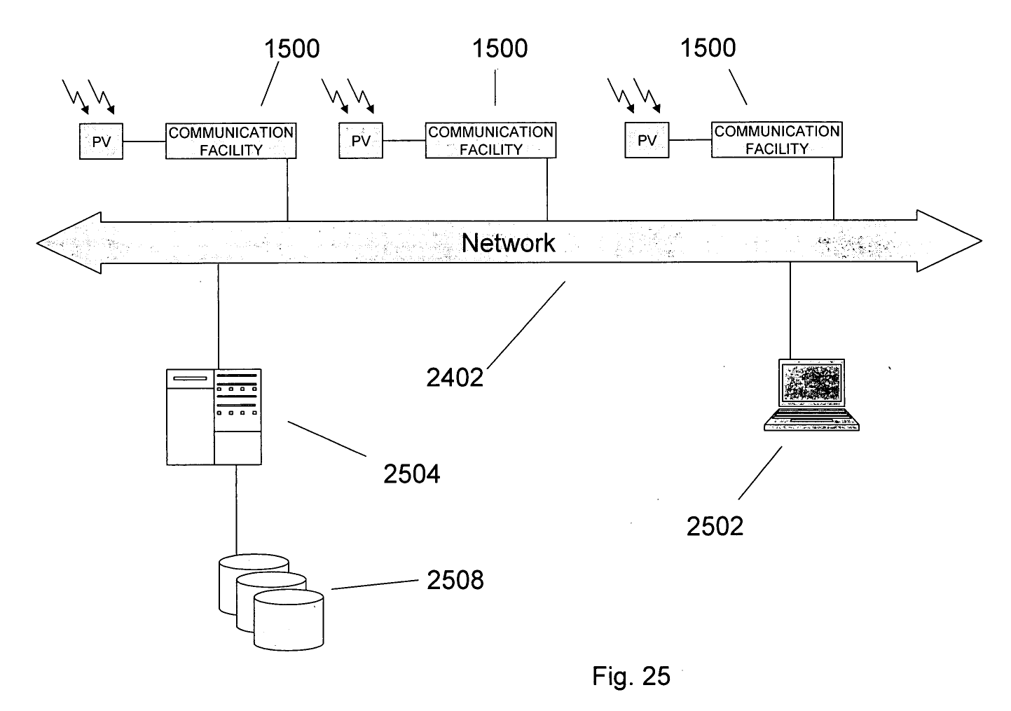

FIG. 25 illustrates a photovoltaic communication facility network according to the principles of the present invention. In embodiments, a photovoltaic communication facility(ies) 1500, or a photovoltaic communication facility associated with other facilities (e.g. those facilities described in connection with FIGS. 15-23) may be associated with a network 2402. For example, a plurality of photovoltaic communication facilities may be adapted to be connected to a network. The photovoltaic communication facilities for example may include transmitters and/or addressable controllers. The network may be a local area network, personal area network, wide area network, the Internet, or other network facility. In embodiments, the network 2402 is associated with a server 2504 and a client computing facility 2502. In embodiments, the server 2504 may be associated with a database and/or set of databases 2508. For example, the photovoltaic communication facilities may communicate information through a network 2402, and the client computing facility may collect the information directly and/or through the server 2504. The server and/or the client computing facility may be adapted to interact with the photovoltaic communication facilities for a number of activities.

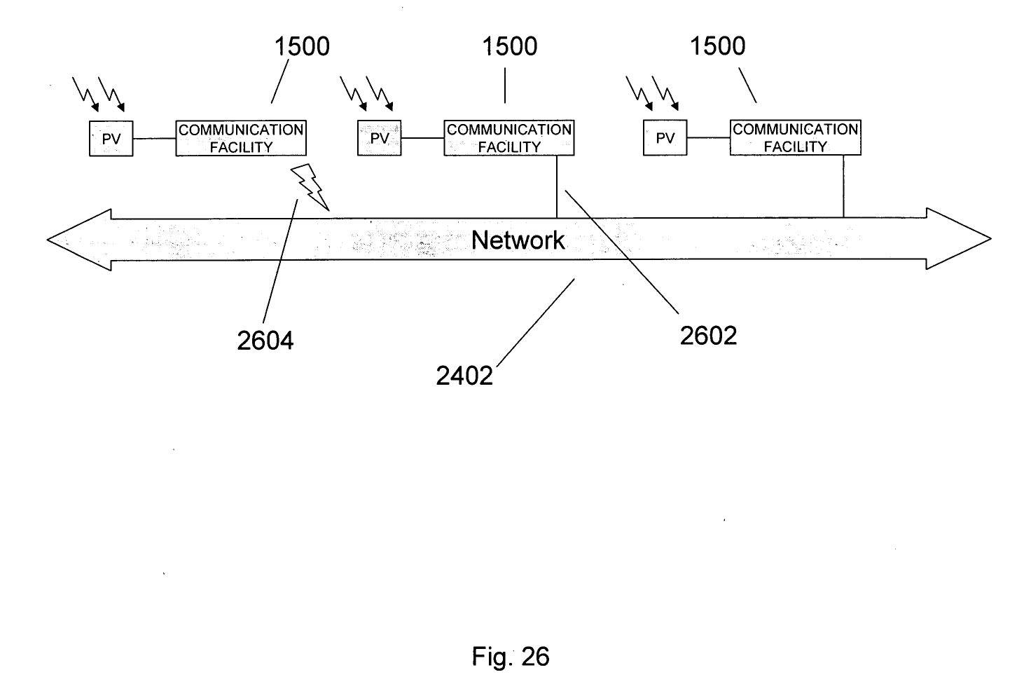

FIG. 26 illustrates a photovoltaic communication facility network according to the principles of the present invention. In embodiments, a photovoltaic communication facility(ies) 1500, or a photovoltaic communication facility associated with other facilities (e.g. those facilities described in connection with FIGS. 15-23) may be associated with a network 2402. For example, a plurality of photovoltaic communication facilities may be adapted to be connected to a network. In embodiments, photovoltaic communication facilities may be adapted to connect (e.g. transmit and/or receive) to the network through wired transmission 2602 or wireless transmission 2604.

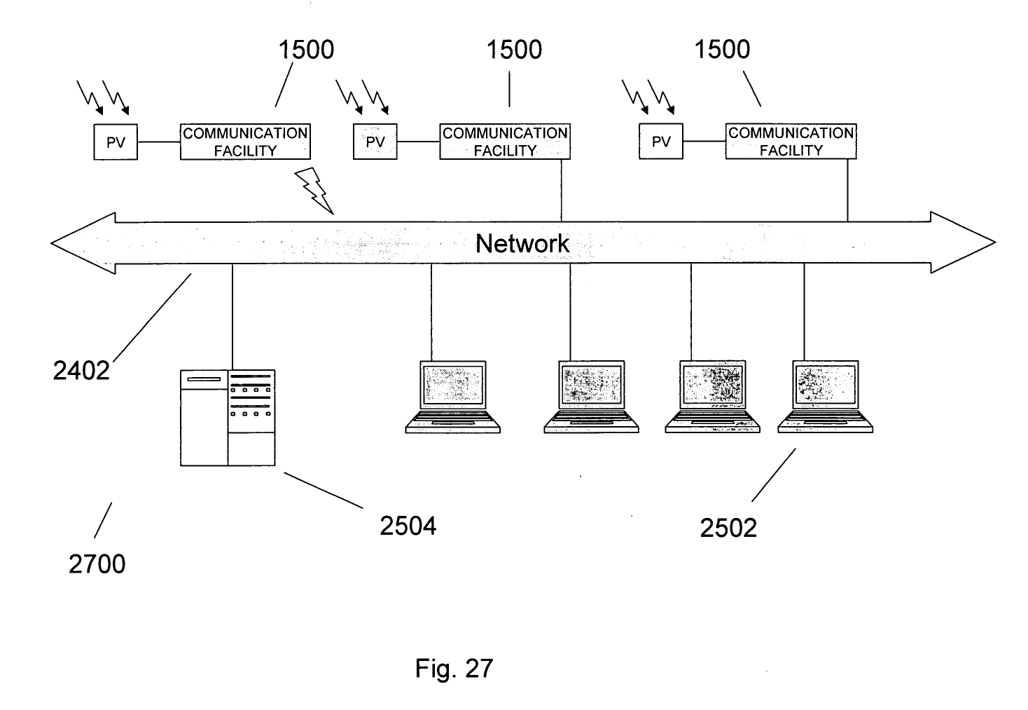

FIG. 27 illustrates a photovoltaic communication facility network 2700 according to the principles of the present invention. In embodiments, a photovoltaic communication facility(ies) 1500, or a photovoltaic communication facility associated with other facilities (e.g. those facilities described in connection with FIGS. 15-23) may be associated with a network 2402. In embodiments, the network 2402 may be a local area network where individual computers 2502 are adapted to communicate via the network and/or communicate with a server.

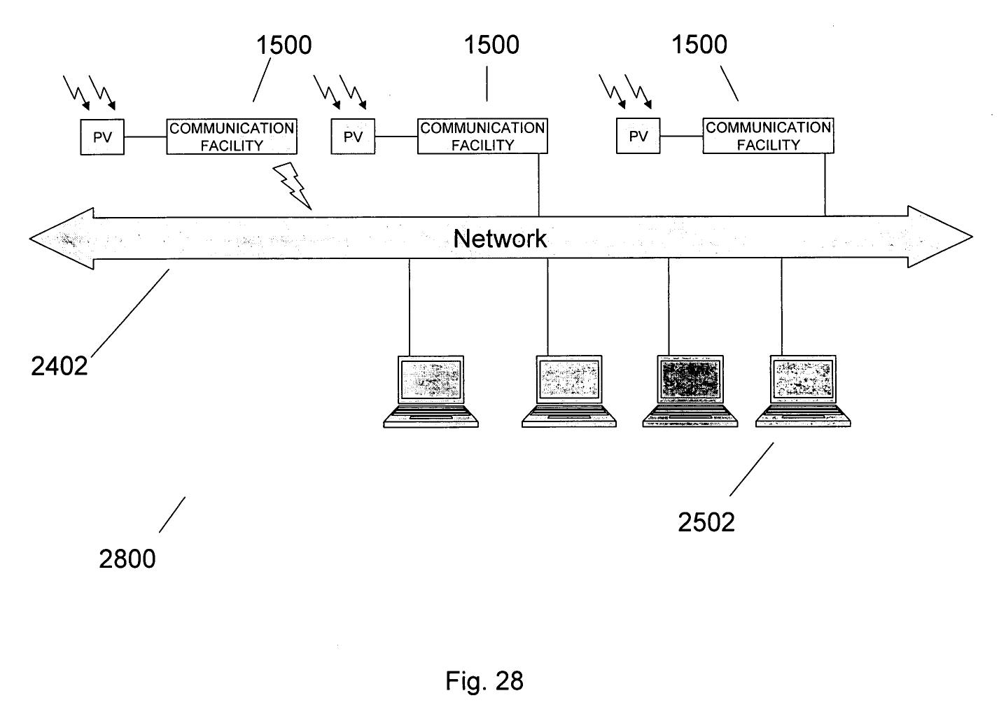

FIG. 28 illustrates a photovoltaic communication facility peer-to-peer network 2800 according to the principles of the present invention. In embodiments, a photovoltaic communication facility(ies) 1500, or a photovoltaic communication facility associated with other facilities (e.g. those facilities described in connection with FIGS. 15-23) may be associated with a peer-to-peer network 2402.

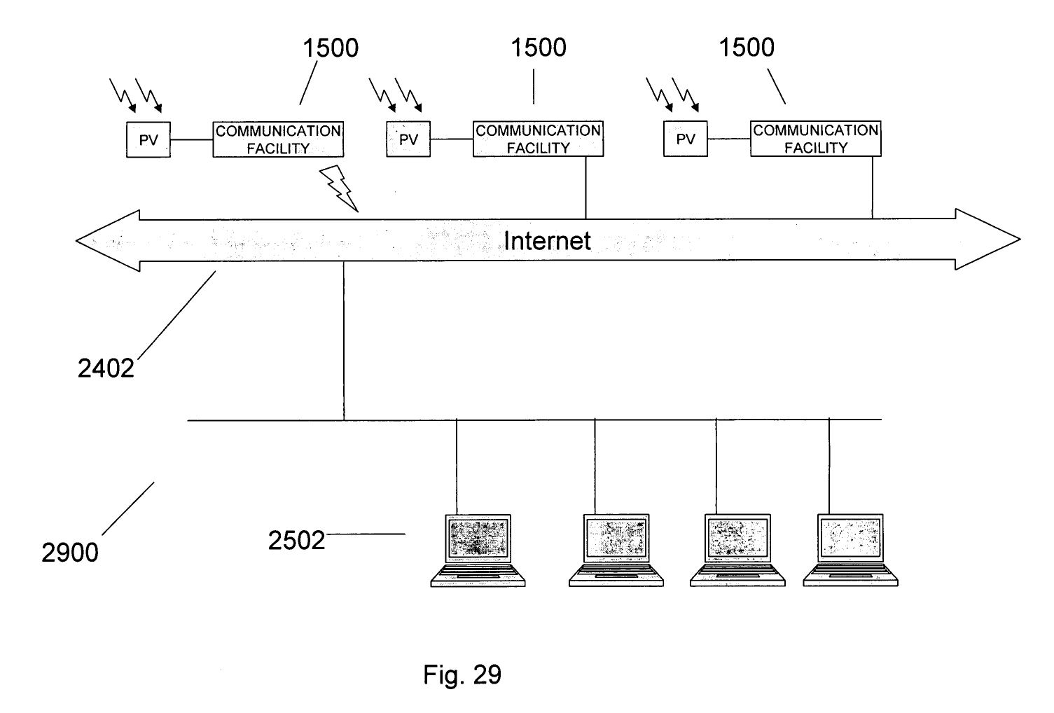

FIG. 29 illustrates a photovoltaic communication facility network 2900 wherein the communication between devices involves the internet according to the principles of the present invention. In embodiments, a photovoltaic communication facility(ies) 1500 or a photovoltaic communication facility associated with other facilities (e.g. those facilities described in connection with FIGS. 15-23) may be associated with the internet 2402.

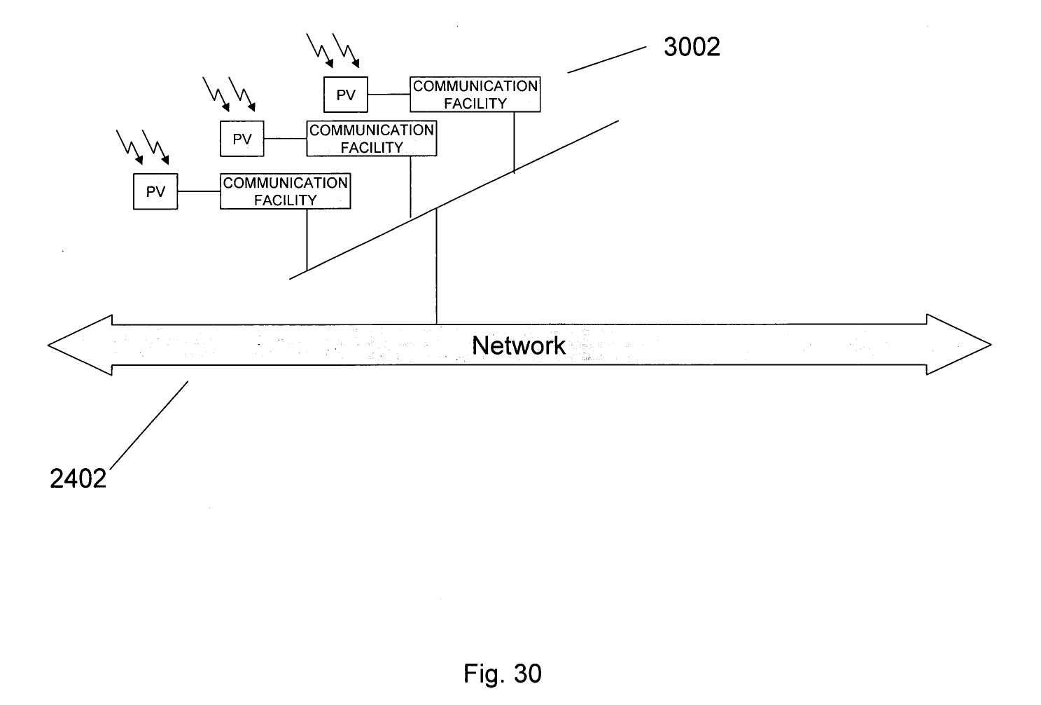

FIG. 30 illustrates a photovoltaic communication facility array 3002 in communication with a network 2402 according to the principles of the present invention. In embodiments, a photovoltaic communication facility(ies) 1500, or a photovoltaic communication facility associated with other facilities (e.g. those facilities described in connection with FIGS. 15-23) may associated in an array, and the array of photovoltaic communication facilities may be associated with the network 2402.

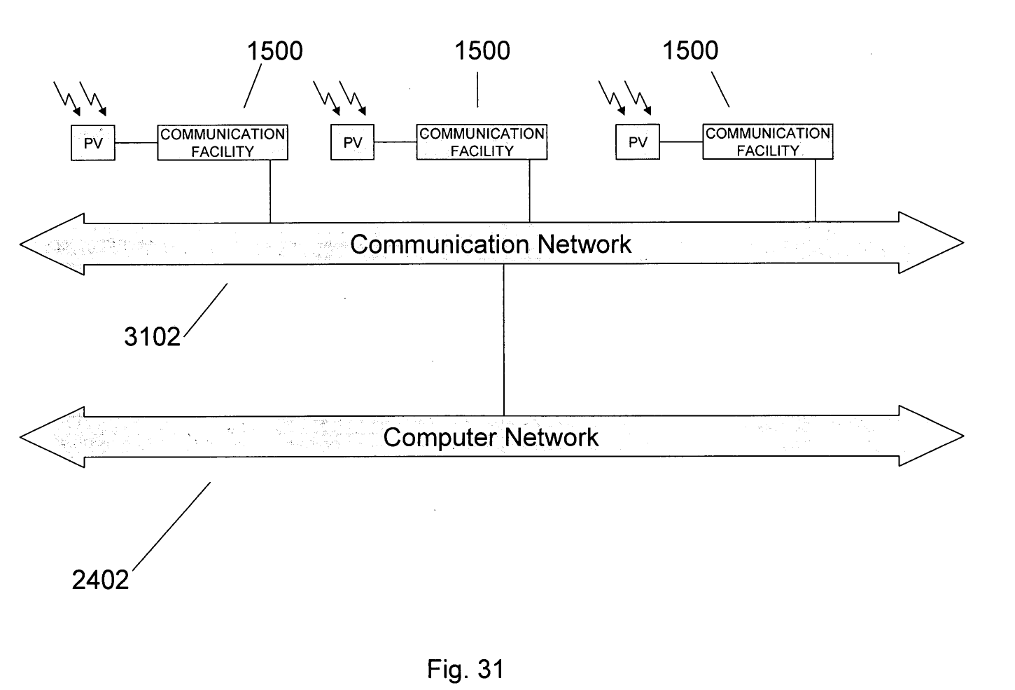

FIG. 31 illustrates several photovoltaic communication facilities arranged on a communication facility network 3102 wherein the network of communication facilities is in communication with a computer network 2402 according to the principles of the present invention. In embodiments, a photovoltaic communication facility(ies) 1500, or a photovoltaic communication facility associated with other facilities (e.g. those facilities described in connection with FIGS. 15-23) may be associated in an array, through a communication facility network, and the array of photovoltaic communication facilities may be associated with the computer network 2402.

An aspect of the present invention relates to photovoltaic variable structures. In embodiments, variable structures may take the form of variable shaped structures. For example, photovoltaic structures may be provided to allow expansion and contraction to fit a particular application, or variable structures may be provided to allow the available power to be varied. In embodiments, variable structures may take the form of folding photovoltaics, flexible photovoltaics, expandable photovoltaics, bendable photovoltaics, shifting structures, and other structures adapted to provide variable structures.

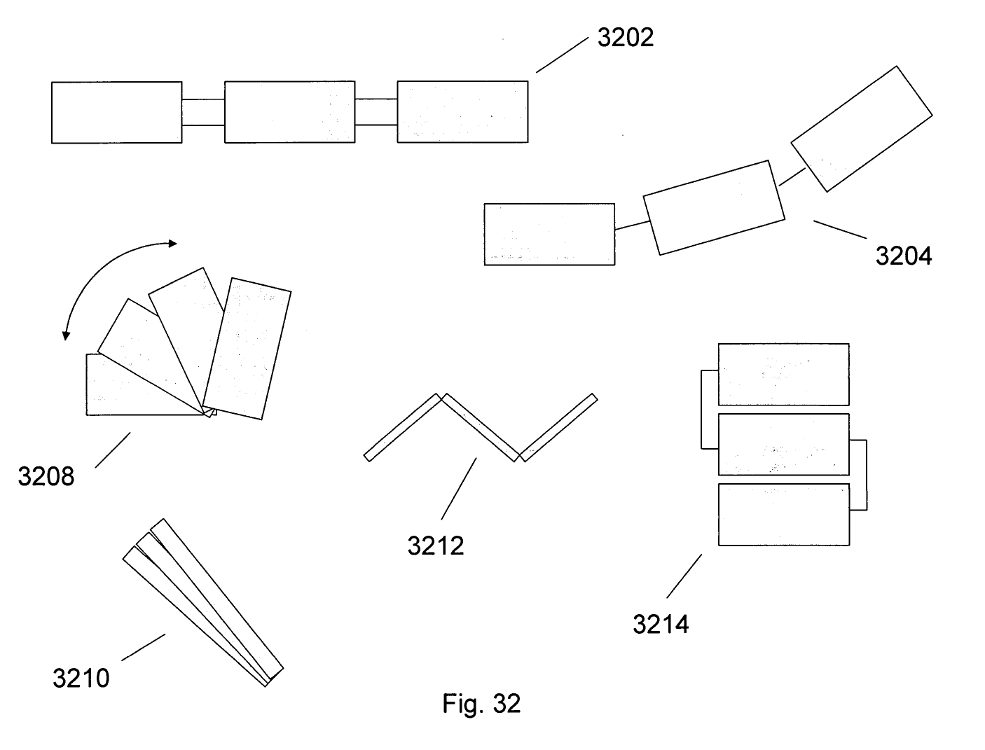

FIG. 32 illustrates several variable photovoltaic structures according to the principles of the present invention. For example, variable structure 3202 illustrates several photovoltaic elements connected through flexible segments. The flexible segments may allow the structure to be folded, bent, curved, or otherwise shaped to fit a particular device, application, or environment. In embodiments, the flexible segments also provide for variable power, voltage, and/or current delivery from the photovoltaic. For example, if one photovoltaic element is folded over another, leaving less exposed active surface area, the photovoltaic will produce less power, voltage, and/or current. In embodiments, this variable structure provides flexible power control suitable to the application, device, and or environment. In embodiments, variable structure photovoltaics include multiple connections, such as variable structure 3202, and some include single element connections, such as 3204. There are many variations to the methods of connecting elements of the photovoltaic structures, for example parallel, series, or other connections, and the present invention is not limited to any particular connection method, and such variants are encompassed by the present invention.

Variable structure 3208 has several photovoltaic elements joined at one corner to provide a fan-like variable photovoltaic structure. Variable structure 3210 has several photovoltaic elements joined at one corner to provide a fan-like variable photovoltaic structure with narrow elements or wings. Variable structure 3214 illustrates an alternating series connection topology connecting several photovoltaic elements. Variable structure 3212 illustrates a compact foldable photovoltaic system where the photovoltaic elements are close together.

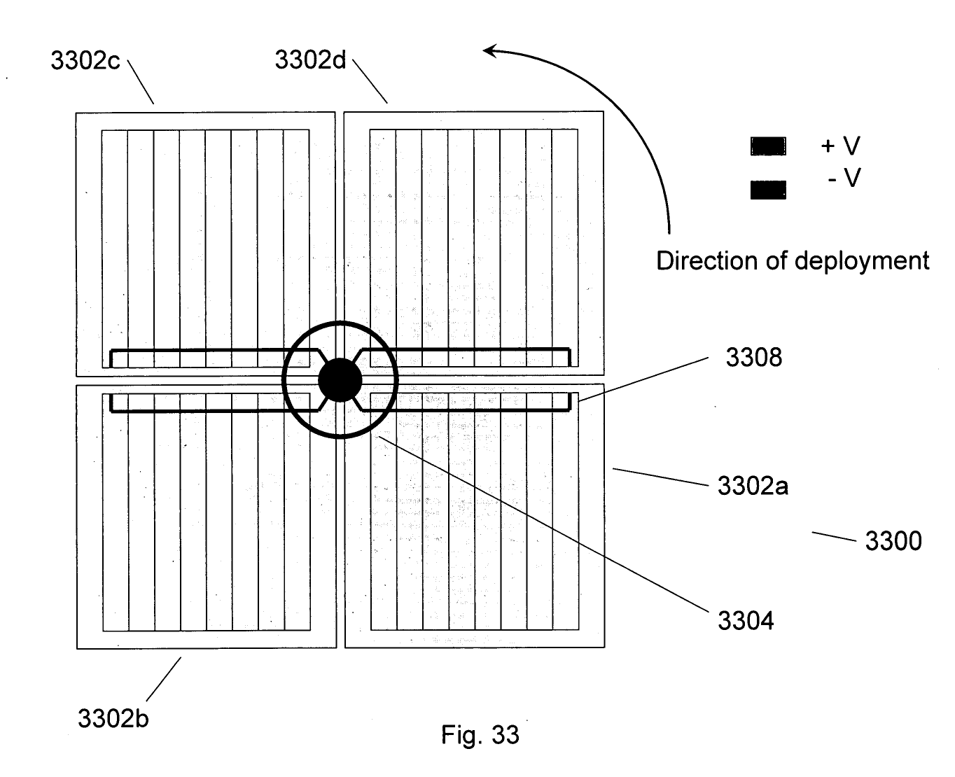

FIG. 33 illustrates a variable photovoltaic structure 3300 wherein the variable photovoltaic structure includes multiple photovoltaic segments 3302 connected through electrical segments which can rotate or be rotated 3304 and 3308. In embodiments, the photovoltaic segments 3302a-d rotate over one another (e.g. in the indicated direction of rotation). The electrical connections 3304 and 3308 for the photovoltaic segments 3302a-d are adapted to remain in electrical association with the photovoltaic segments during rotation. For example, electrical connection 3304 is circular to retain connection with the negative poles of the photovoltaic segments while the segments are rotated, and electrical segments 3308 are linear and connect with a center rotational point to remain electrically connected with the positive poles of the photovoltaic segments. It should be appreciated that the present invention is not limited to any particular electrical or mechanical connection facility, and there are many other electrical connections envisioned and encompassed by the present invention. For example, each photovoltaic segment may be connected to positive and negative electrical connections, and the several electrical connections may be attached directly or without secondary rotational components. A connection facility may also involve capacitive, inductive, or other electrical connection facilities. In embodiments, the rotatable segments may be provided for a flexibly shaped photovoltaic facility. In embodiments, the rotatable segments may be provided to provide a variable power photovoltaic facility. For example, as the photovoltaic segments are rotated over one another, the exposed surface area may be reduced, and the reduction in exposed surface area may result in reduced power generation.

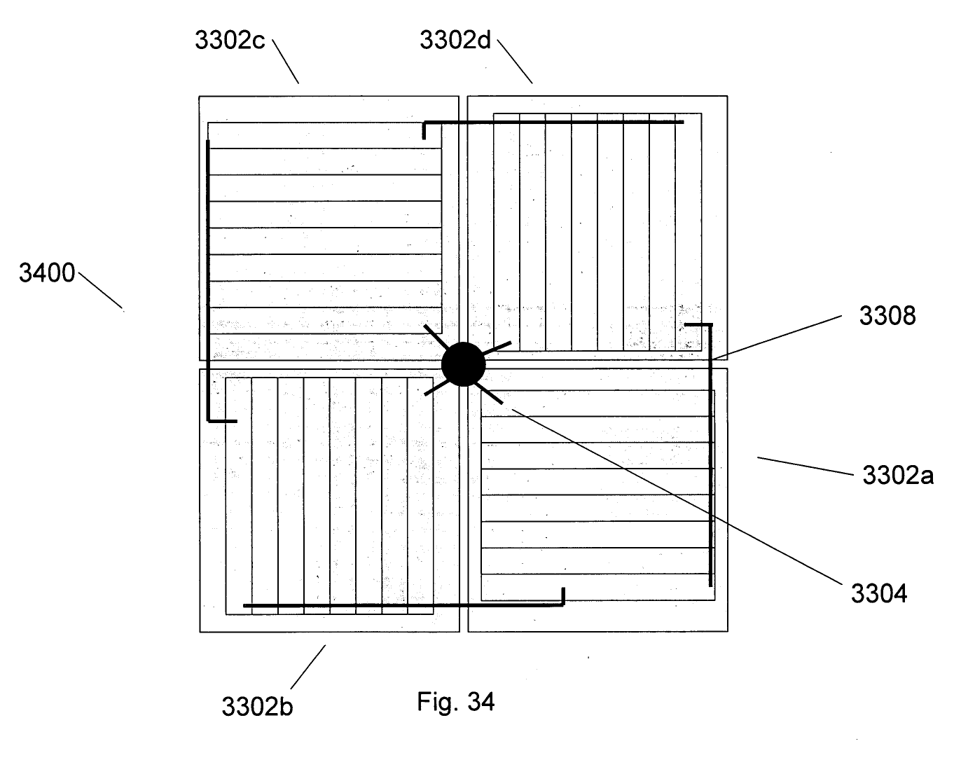

FIG. 34 illustrates another variable photovoltaic structure 3400 wherein the variable photovoltaic structure includes multiple photovoltaic segments 3302 connected through foldable electrical segments 3304 and 3308. In this embodiment, the several segments may be folded over one another. In embodiments, the foldable segments may provide a variable power photovoltaic facility. For example, as the photovoltaic segments are folded over one another, the exposed surface area may be reduced, and the reduction in exposed surface area may result in reduced power generation.

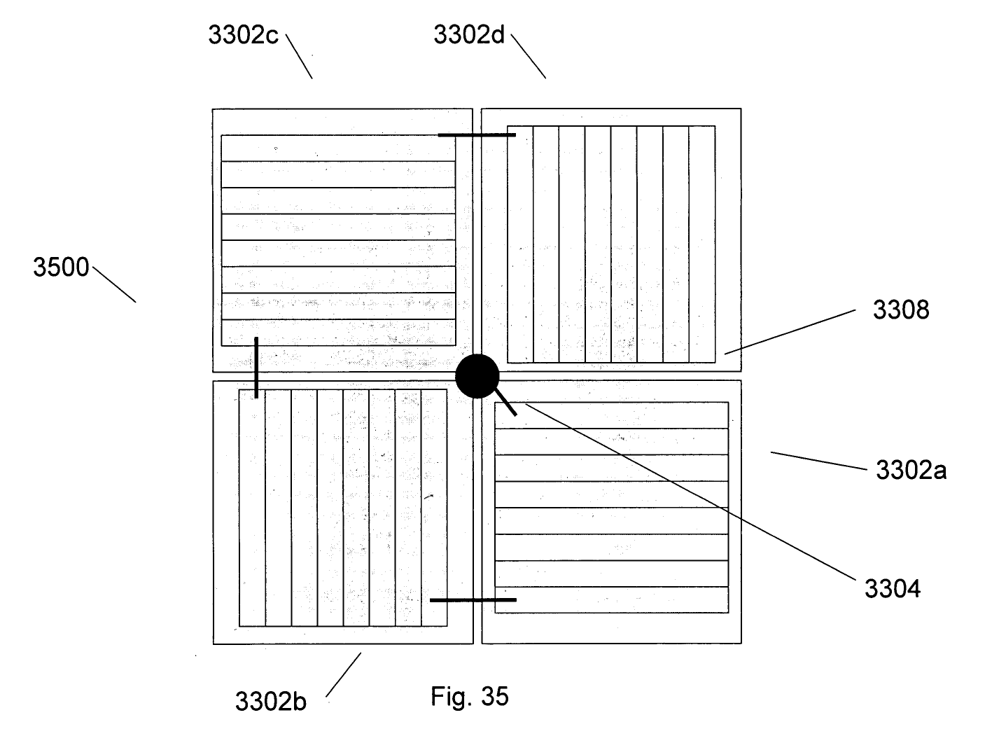

FIG. 35 illustrates another variable photovoltaic structure 3500 wherein the variable photovoltaic structure includes multiple photovoltaic segments 3302 connected through foldable electrical segments 3304 and 3308. In this embodiment, the several segments may be folded over one another. In embodiments, the foldable segments may provide a variable power photovoltaic facility. For example, as the photovoltaic segments are folded over one another, the exposed surface area may be reduced, and the reduction in exposed surface area may result in reduced power generation.

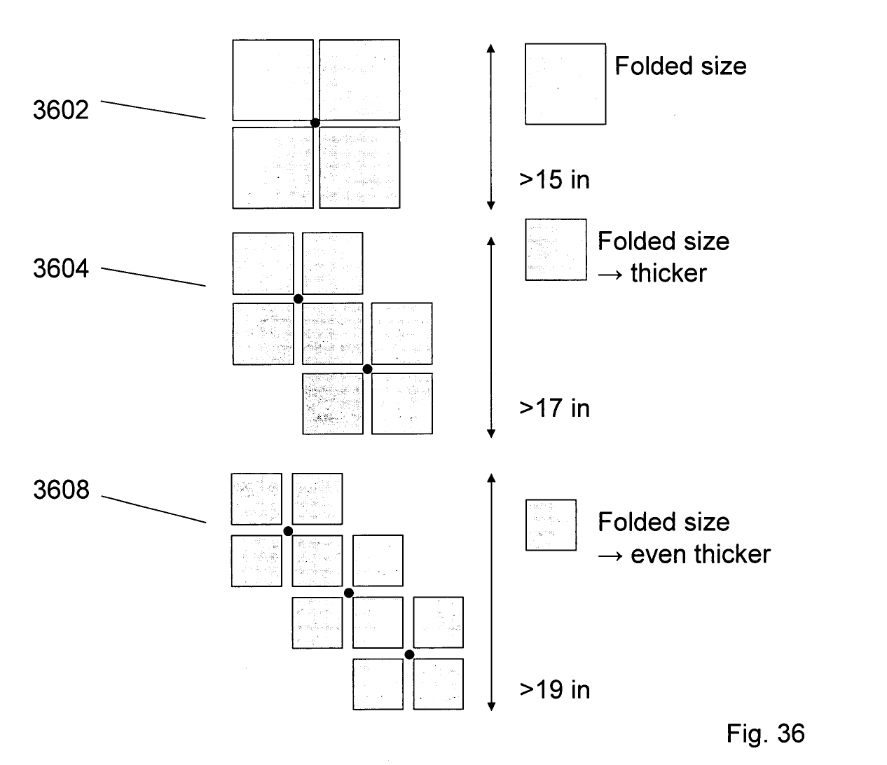

FIG. 36 illustrates several variable photovoltaic structures according to the principles of the present invention. In embodiments, the variable photovoltaic structures may be produced in a number of shapes with various sizes. For example, foldable photovoltaic structure 3602 includes four foldable photovoltaic segments; foldable photovoltaic structure 3604 includes seven foldable segments, and foldable photovoltaic structure 3608 includes ten foldable segments. While the illustrations in FIG. 36 indicate the structures with more segments can be folded into a smaller footprint, this is not required for all embodiments. For example, a variable photovoltaic structure may include photovoltaic segments similar in size to those of foldable photovoltaic structure 3602 but include seven, ten, more or less segments, which when folded take up approximately the same footprint of a folded foldable photovoltaic structure 3602. In embodiments, some or all of the segments may be folded to reduce the footprint and/or reduce the power generation. In embodiments, the foldable segments may be arranged to reduce the footprint but retain approximately the original exposed photovoltaic area to retain the original generation ability. In embodiments, foldable photovoltaic segments may be folded like a paper airplane, including many variants.

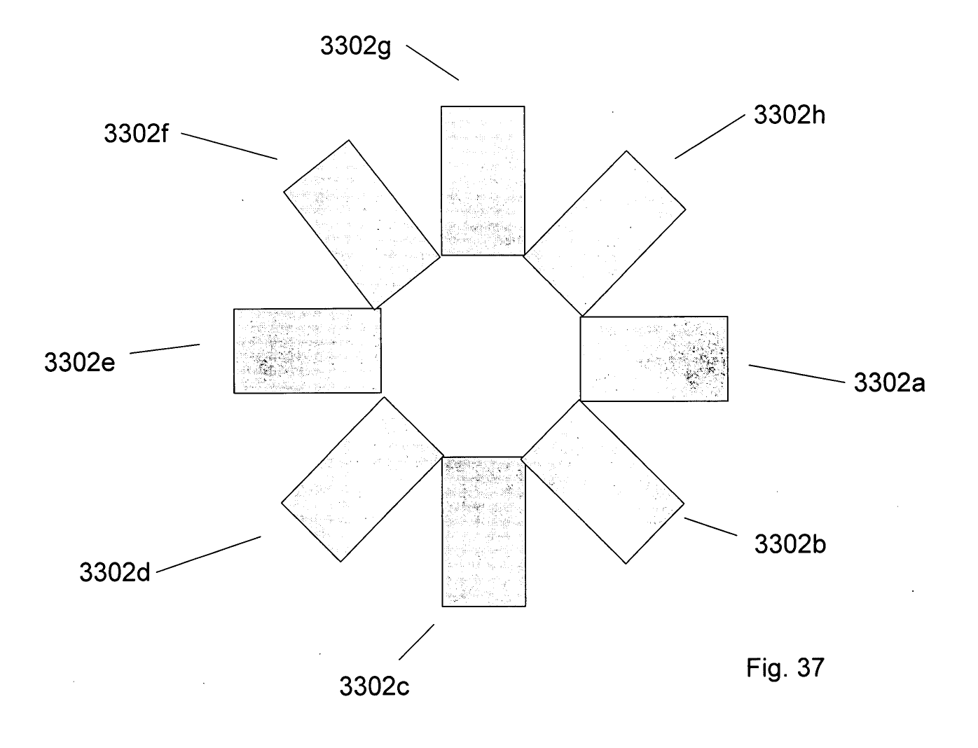

FIG. 37 illustrates a variable photovoltaic structure 3700 with eight foldable segments 3302. In embodiments, the foldable segments 3302a-h may be individually folded, folded in groups, folded as a group, folded in a forward direction, folded in a reverse direction, partially folded in a forward direction and partially folded in a reverse direction, or otherwise folded.

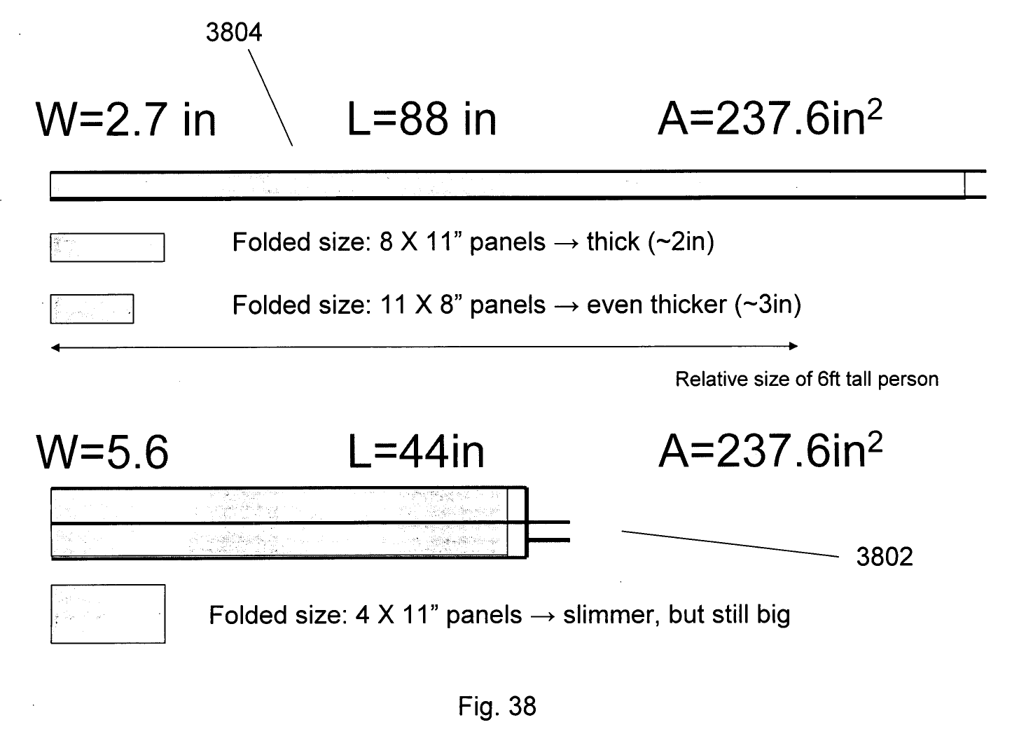

FIG. 38 illustrates several variable photovoltaic structures according to the principles of the present invention. For example, foldable photovoltaic structure 3802 may include four eleven inch panels and fully extend to forty-four inches. Foldable photovoltaic structure 3804 may include eight eleven-inch panels and fully extend to eighty-eight inches. Foldable photovoltaic structure may include eleven eight-inch segments and fully extend to eighty-eight inches. In embodiments, the foldable photovoltaic structures may be fully extended, or fully unfolded, and/or partially extended.

In embodiments a variable photovoltaic structure may be formed with a printed flexible circuit as substrate (e.g. in an array). In embodiments, the photovoltaic segments in the variable photovoltaic structure may be electrically connected in series or in parallel, a combination of series and parallel connections, or other suitable electrical connection scheme.

In embodiments, a variable photovoltaic structure may be formed to fit in pockets, on a desk, on a surface, on a device, on a notebook computer, or on, in, or around another device. In embodiments, a variable photovoltaic structure may be offered that provides flexibility in producing certain voltage, current, and/or power based on the flexible layout and/or footprint.

In embodiments, a variable photovoltaic structure may take on a form similar to a fan. The structure may be foldable for example, and/or it may rotate around an axis that lies in the plane of the module. The fan may rotate outside the plane that the module lies in. The structure may include a central electrical component in which the panels can fan out into a desired orientation. In embodiments, the electrical connections may be on opposite vertices (e.g. on squares, rectangles, etc). In embodiments, the variable structure may be optimized for volume stored and/or footprint stored.

In embodiments, a fan may include a preset X dimension (e.g. to determine voltage) but not have a preset Y dimension, to allow for the optimization of Y and Z dimensions. That is, trade off one dimension of a panel versus the thickness of the stack.

In embodiments, square photovoltaic structures are connected at opposite vertices and may have as many as one wants, folded or fanned, and with or without shadowing. In embodiments, the structure may open about a Z axis; they may stack and then open up around that axis. In embodiments, a stack of cells that is movably disposed about a Z axis is provided.

In embodiments, the photovoltaic structures are provided in a stack but not connected while in the stack. They can be removed from the stack like a deck of cards and then reconnected through plugs and/or other connection facilitators. The structures may also include clips that mechanically hold the structures together.

In embodiments, the variable photovoltaic structures are provided in a form similar to a Chinese Fan, and the fan may spread out in angles up to 360 degrees, depending on the structure and/or desired effect. In embodiments, the fan structure does not use segments that are parallel edged.

In embodiments, a variable photovoltaic structure may be shipped in a deployable format (e.g. stacked up into a package that folds up and is deployable on removal from the package). For example, if tension is applied on the two vertices in opposite directions, the structure folds and unfolds on itself without mechanical intervention. Embodiments include a communication facility in a box (e.g. it builds itself out as you open it up). In embodiments, a stack may deploy without breaking, may deploy itself, and may also perform self-orientation.

In embodiments, the variable photovoltaic structure is formed as an accordion. Not every membrane is supported by a piece of plastic—don't support every piece with injection-molded plastic and piano-type hinges.

In an embodiment, a flexible photovoltaic may have a certain output under flex and a different output when not flexed.

An aspect of the present invention involves providing a communication facility-feedback tracking of a light source. In embodiments, a communication facility is provided to communicate light intensity and a positioning facility (e.g. a motor) may be used to reposition the photovoltaic segment. In embodiments, the repositioning is performed to obtain optimal light intensity exposure, some light intensity exposure, constant light exposure, variable light exposure, reduced light exposure, or other reason.

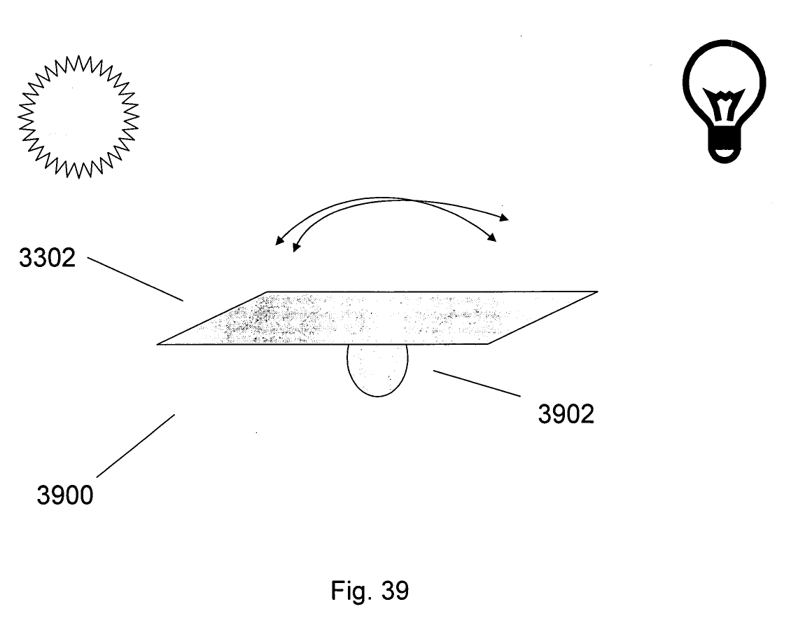

FIG. 39 illustrates a variable photovoltaic structure 3900 adapted to sense light and position itself in relation to the light in accordance with the principles of the present invention. For example, the variable photovoltaic structure may include a photovoltaic panel 3302, a light sensor (not shown), a communication facility (not shown) and a positioning facility 3902 (e.g. a motor, micro-motor, MEMS motor, servo, rotating member, or movable member), and the information from the light sensor may be fed back into a processor (not shown). The processor may then adjust the position of the photovoltaic panel 3302 in relation to the information received from the light sensor. The processor may also receive information regarding light from a communication facility. In embodiments, the panel is movable in one plane, two planes, multiple planes, continuous planes, discrete planes, discrete positions, or other suitable positions. In embodiments, the variable photovoltaic structure 3900 may be adapted to measure light from more than one light source and adjust its position accordingly. The variable photovoltaic structure 3900 may also be adapted to receive communications regarding light from multiple sources and adjust position accordingly.

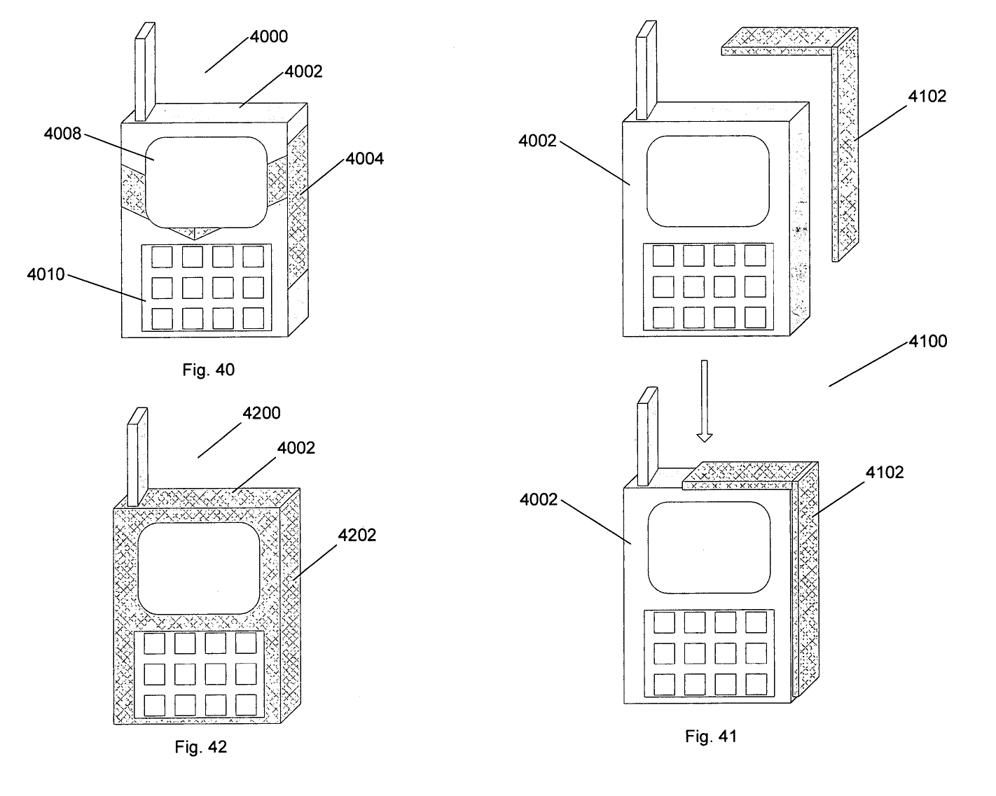

FIG. 40 depicts a mobile communication facility 4002 in association with a flexible photovoltaic facility 4004. The mobile communication facility may have a display 4008 and/or a keypad 4010. The flexible photovoltaic facility 4004 may be adapted to conform to at least a portion of the outer surface of the mobile communication facility 4002. The flexible photovoltaic facility 4004 may be any of the photovoltaic facilities described herein and may be produced by any of the methods described herein. The flexible photovoltaic facility 4004 may comprise a mesh and may have plastic-like, cloth-like and/or fabric-like properties. The flexible photovoltaic facility 4004 may be composed of at least one photovoltaic fiber. The photovoltaic facility 4004 may be printed onto the mobile communication facility 4002.

The mobile communication facility 4002 may be a handheld communication facility. The mobile communication facility 4002 may be a portable communication facility. The mobile communication facility 4002 may be a cell phone, a satellite phone, a cordless phone, a cordless phone handset, a personal digital assistant, a palmtop computer, a laptop computer, a computing device, a transponder, a pager and/or a walkie talkie.

In embodiments, the flexible photovoltaic facility 4004 may directly power the mobile communication facility 4002. The flexible photovoltaic facility may be associated with a filtering facility, regulation facility and/or transformer to filter, regulate and/or transform certain properties of the power generated by the flexible photovoltaic facility 4004. In embodiments, the flexible photovoltaic facility 4004 may also be associated with an energy storage facility for storing energy generated by the photovoltaic facility. The energy storage facility may be a battery and/or a capacitor.

In embodiments, the flexible photovoltaic facility 4004 may be aesthetically customized. The flexible photovoltaic facility 4004 may create or have a distinct appearance. The distinct appearance may be created by the certain properties of the flexible photovoltaic facility 4004. The photovoltaic facility may absorb or transmit light with selected properties.

FIG. 41 depicts a mobile communication facility 4002 in association with a photovoltaic face plate 4102. As shown in FIG. 41, the photovoltaic face plate 4102 may snap or click onto the mobile communication facility 4002. In embodiments, the face plate 4102 may be interchanged among mobile communication facilities 4002. All or only a portion of the face plate 4102 may have photovoltaic properties. The photovoltaic facility may be printed onto the face plate 4102 or otherwise associated with the face plate 4102. The photovoltaic face plate 4102 may be flexible. The face plate 4102 may act as a protective covering for the mobile communication facility 4002.

The photovoltaic face plate 4102 may be any of the photovoltaic facilities described herein and may be produced by any of the methods described herein. The photovoltaic face plate 4102 may comprise a mesh and may have plastic-like, cloth-like and/or fabric-like properties. The photovoltaic face plate 4102 may be composed of at least one photovoltaic fiber. The photovoltaic facility or facilities may be printed onto the photovoltaic face plate 4102.

The photovoltaic face plate 4102 may be aesthetically customized. The photovoltaic face plate 4102 may create or have a distinct appearance. The distinct appearance may be created by the certain properties of the photovoltaic facility or facilities associated with the face plate 4102. The associated photovoltaic facility or facilities may absorb or transmit light with selected properties.

In embodiments, the photovoltaic face plate 4102 may directly power the mobile communication facility 4002. The photovoltaic face plate 4102 may be associated with a filtering facility, regulation facility and/or transformer to filter, regulate and/or transform certain properties of the power generated by the photovoltaic face plate 4102. In embodiments, the photovoltaic face plate 4102 may also be associated with an energy storage facility for storing energy generated by the photovoltaic face plate 4102. The energy storage facility may be a battery and/or a capacitor.

FIG. 42 illustrates a mobile communication facility 4002 in association with a photovoltaic skin 4202. In embodiments, the photovoltaic skin 4202 may cover the entire surface of the mobile communication facility 4002 or only a portion of the surface of the mobile communication facility 4002. The photovoltaic skin 4202 may be one piece. The photovoltaic skin 4202 may be any of the photovoltaic facilities described herein and may be produced by any of the methods described herein. The photovoltaic skin 4202 may comprise a mesh and may have plastic-like, cloth-like and/or fabric-like properties. The photovoltaic skin 4202 may be flexible. The photovoltaic skin 4202 may be composed of at least one photovoltaic fiber. The photovoltaic facility or facilities may be printed onto the photovoltaic skin 4202.

In embodiments, the photovoltaic skin 4202 may directly power the mobile communication facility 4002. The photovoltaic skin 4202 may be associated with a filtering facility, regulation facility and/or transformer to filter, regulate and/or transform certain properties of the power generated by the flexible photovoltaic facility 4004. In embodiments, the photovoltaic skin 4202 may also be associated with an energy storage facility for storing energy generated by the photovoltaic facility. The energy storage facility may be a battery and/or a capacitor.

The photovoltaic skin 4202 may be flexible and formed to the mobile communication facility 4002. The photovoltaic skin 4202 may act as a protective covering for the mobile communication facility 4002. The photovoltaic skin 4202 may be aesthetically customized. The photovoltaic skin 4202 may create or have a distinct appearance. The distinct appearance may be created by the certain properties of the photovoltaic facility or facilities associated with the skin 4202. The associated photovoltaic facility or facilities may absorb or transmit light with selected properties.

The photovoltaic skin 4202 may be associated with the mobile communication facility 4002 during manufacturing. The photovoltaic skin 4202 may be applied to the mobile communication facility after the manufacturing of the mobile communication facility 4002. The photovoltaic skin 4202 may be applied to the mobile communication facility 4002 in a liquid or amorphous form and may change form over time.

In embodiments, the photovoltaic systems described herein may be combined and offered as a kit. The kit may be offered for sale in a channel appropriate for the applications and environments. The kit may include a mobile communication facility 4002 in association with one or more flexible photovoltaic facilities 4004, photovoltaic face plates 4102 and/or photovoltaic skins 4202.

While the invention has been described in connection with certain preferred embodiments, it should be understood that other embodiments would be recognized by one of ordinary skill in the art, and are incorporated by reference herein.

What is claimed is:

1. A method, comprising providing a mobile communication facility in association with a flexible photovoltaic facility adapted to conform to at least a portion of the outer surface of the communication facility.

2. The method of claim 1, wherein the mobile communication facility comprises at least one of a handheld and portable communication facility.

3. The method of claim 1, wherein the mobile communication facility is selected from the group consisting of: a cell phone, a satellite phone, a cordless phone, a cordless phone handset, a personal digital assistant, a palmtop computer, a laptop computer, a computing device, a transponder, a pager and a walkie talkie.

4. The method of claim 1, wherein the photovoltaic facility powers the mobile communication facility.

5. The method of claim 1, further comprising providing at least one of a filtering facility, a regulation facility and a transformer.

6. The method of claim 1, further comprising providing an energy storage facility for storing energy generated by the photovoltaic facility.

7. The method of claim 1, wherein the photovoltaic facility is printed onto the mobile communication facility.

8. The method of claim 1, wherein the flexible photovoltaic facility has mesh-like properties.

9. The method of claim 1, wherein the flexible photovoltaic facility is composed of at least one photovoltaic fiber.

10. A method, comprising providing a mobile communication facility in association with a photovoltaic face plate.

11. The method of claim 10, wherein the photovoltaic face plate is flexible.

12. The method of claim 10, wherein the photovoltaic face plate may snap onto the mobile communication facility.

13. The method of claim 10, wherein the photovoltaic face plate may be interchanged among mobile communication facilities.

14. The method of claim 10, wherein the photovoltaic face plate is aesthetically customized.

15. The method of claim 10, wherein the photovoltaic face plate absorbs light with selected properties.

16. The method of claim 10, wherein the photovoltaic face plate transmits light with selected properties.

17. A method, comprising providing a mobile communication facility in association with a photovoltaic skin.

18. The method of claim 17, wherein the photovoltaic skin may be associated with the mobile communication facility during manufacturing.

19. The method of claim 17, wherein the photovoltaic skin may be applied to the mobile communication facility after the manufacturing of the mobile communication facility.

20. The method of claim 17, wherein the photovoltaic skin may be flexible and formed to the mobile communication facility.
